(19) United States
(12) Patent Application Publication
(10) Pub. No.: US 2022/0244367 A1
(43) Pub. Date: Aug. 4, 2022

(54) Measurements using an ultra-wideband ranging pair

(71) Applicant: GOOGLE LLC, Mountain View, CA (US)

(72) Inventors: Dongeek Shin, Santa Clara, CA (US); Richard Lee Marks, Pleasanton, CA (US)

(21) Appl. No.: 17/248,672

(22) Filed: Feb. 2, 2021

(51) Int. Cl. G01S 11/04; G06F 3/01

(52) U.S. Cl. CPC G01S 11/04; H04N 5/23296; G06F 3/011

(57) ABSTRACT

A method including associating an ultra-wide band (UWB) tag device with a UWB anchor device, capturing UWB range and angle data representing a plurality of locations in a physical space using a calibration technique, capturing UWB range and angle data representing a first location of the UWB tag device in relation to the UWB anchor device, capturing UWB range and angle data representing a second location of the UWB tag device in relation to the UWB anchor device, and determining a length based on the first location and the second location.

### RELATED APPLICATION

This application is related to the application with Attorney Docket No. 0059-884WO1, titled “SPATIALLY-AWARE CONTROLLER USING ULTRA-WIDEBAND TESSELLATION” and being filed on the same date as this application, the entirety of which is incorporated by reference herein.

### FIELD

Embodiments relate to smart device control in a physical space. Embodiments relate to using a smart device controller as a measurement device.

### BACKGROUND

Smart devices have become prevalent within the home and other physical spaces. With a voice query or a physical gesture, a user can cause a smart device to trigger an action (e.g., lights on/off, television channel change, appliance control, and/or the like) without physical interaction.

### SUMMARY

In a general aspect, a device, a system, a non-transitory computer-readable medium (having stored thereon computer executable program code which can be executed on a computer system), and/or a method can perform a process with a method including associating an ultra-wide band (UWB) tag device with a UWB anchor device, capturing UWB range and angle data representing a plurality of locations in a physical space using a calibration technique, capturing UWB range and angle data representing a first location of the UWB tag device in relation to the UWB anchor device, capturing UWB range and angle data representing a second location of the UWB tag device in relation to the UWB anchor device, and determining a length based on the first location and the second location.

Implementations can include one or more of the following features. For example, at least one range associated with the UWB data can be non-linear corrected using a trained polynomial regression model. The length can be determined as the Euclidean norm of the difference in the cartesian coordinates of the first location and the second location. The length can be a circumference of a circle that can be determined using a Riemann sum over a set of locations including the first location and the second location. The capturing of UWB range and angle data can include transmitting a first signal from the UWB anchor device to the UWB tag device, determining a delay time associated with a second signal received, in response to the first signal, by the UWB anchor device from the UWB tag device, determining a distance based on the delay time, determining an angle-of-arrival (AoA) based on the first signal and the second signal, and determining two-dimensional (2D) coordinates corresponding to the location of the UWB tag device.

For example, the calibration technique can be a first calibration technique and the UWB tag device can be an element of augmented reality (AR) glasses, the method can further include capturing UWB range and angle data representing a plurality of object locations using a second calibration technique associating the UWB range and angle data representing one of the plurality of object locations with the UWB range and angle data representing a first location, associating UWB range and angle data corresponding to a location of the AR glasses with the UWB range and angle data representing a second location, and warning a user of the AR glasses when the determined length is less than a threshold length value. The calibration technique can be a first calibration technique and the UWB tag device can be an element of AR glasses, the method can further include capturing UWB range and angle data representing a plurality of object locations using a second calibration technique, associating the UWB range and angle data representing one of the plurality of object locations with the UWB range and angle data representing a first location, associating UWB range and angle data corresponding to a location of the AR glasses with the UWB range and angle data representing a second location, and focusing a camera of the AR glasses based on the determined length.

For example, the calibration technique can be a first calibration technique and the UWB tag device can be an element of AR glasses, the method can further include capturing UWB range and angle data representing a plurality of object locations using a second calibration technique, determining the user of the AR glasses is focused on an object of the plurality of objects, and in response to determining the user of the AR glasses is focused on an object of the plurality of objects associating the UWB range and angle data representing the object location with the UWB range and angle data representing a first location, associating UWB range and angle data corresponding to a location of the AR glasses with the UWB range and angle data representing a second location, and zooming a lens of a camera of the AR glasses based on the determined length for displaying the object on a display of the AR glasses. The calibration technique can be a first calibration technique and the UWB tag device can be an element of AR glasses, the method can further include capturing UWB range and angle data representing a plurality of object locations using a second calibration technique, determining the user of the AR glasses is looking for an object of the plurality of objects, and in response to determining the user of the AR glasses is looking for an object of the plurality of objects associating the UWB range and angle data representing the object location with the UWB range and angle data representing a first location, associating UWB range and angle data corresponding to a location of the remaining objects of the plurality of objects with the UWB range and angle data representing a second location, and blurring or focusing a display of the AR glasses based on the determined length.

For example, the calibration technique can be a first calibration technique and the UWB tag device can be an element of AR glasses, the method can further include capturing UWB range and angle data representing a plurality of object locations using a second calibration technique, associating UWB range and angle data a virtual reality (VR) object, associating the UWB range and angle data representing the VR object location with the UWB range and angle data representing a first location, associating UWB range and angle data corresponding to a location of the AR glasses with the UWB range and angle data representing a second location, determining whether the user of the AR glasses is within a range of the VR object based on the determined length, and in response to determining whether the user of the AR glasses is within the range of the VR object, initiating a VR action by the VR object. The calibration technique can be a first calibration technique and the UWB tag device is an element of AR glasses, the method can further include capturing UWB range and angle data representing a plurality of object locations using a second calibration technique, associating UWB range and angle data a virtual reality (VR) object, associating the UWB range and angle data representing the VR object location with the UWB range and angle data representing a first location, associating UWB range and angle data corresponding to a location of the objects of the plurality of objects with the UWB range and angle data representing a second location, determining the user of the VR glasses is looking at the VR object, and in response to determining the user of the VR glasses is looking at the VR object, adjusting an opaqueness of the VR object based on the plurality of objects along a line of sight and the determined length.

For example, the calibration technique can be a first calibration technique, the method can further include capturing UWB range and angle data representing a plurality of object locations using a second calibration technique, determining a user in possession of the UWB tag device has initiated a media casting operation, and in response to determining the user has initiated a media casting operation associating the UWB range and angle data representing each of the plurality of object locations with the UWB range and angle data representing a first location, associating UWB range and angle data corresponding to a location of the AR glasses with the UWB range and angle data representing a second location, determining whether a device capable of receiving and displaying the media casting is within a range of the user based on the determined length, and in response to determining a device capable of receiving and displaying the media casting is within the range of the user, casting the media to the device. The method can further include determining the user is no longer in range of the device capable of receiving and displaying the media based on the length, determining the user is in range of a second device capable of receiving and displaying the media based on the determined length, and in response to determining second device capable of receiving and displaying the media casting is within the range of the user, ending the casting of the media to the device and casting the media to the second device.

For example, the calibration technique can be a first calibration technique, the method can further include capturing UWB range and angle data representing a plurality of light locations using a second calibration technique, associating the UWB range and angle data representing one of the plurality of light locations with the UWB range and angle data representing a first location, associating UWB range and angle data corresponding to a location of a user in possession of the UWB tag device with the UWB range and angle data representing a second location, determining whether the user is within a range of a light based on the determined length, in response to determining whether the user is within the range of a light, causing the light to turn on, and in response to determining whether the user is not within the range of a light, causing the light to turn off.

### BRIEF DESCRIPTION OF THE DRAWINGS

Example embodiments will become more fully understood from the detailed description given herein below and the accompanying drawings, wherein like elements are represented by like reference numerals, which are given by way of illustration only and thus are not limiting of the example embodiments and wherein:

FIG. 1 illustrates a pictorial representation of a system for determining user position, spatial context and localization according to at least one example embodiment.

FIG. 2A illustrates a block diagram of signals communicated between an anchor and a tag according to at least one example embodiment.

FIG. 2B illustrates a graphical diagram of ranging according to at least one example embodiment.

FIG. 2C illustrates a block diagram of determining an angle-of-arrival (AoA) according to at least one example embodiment.

FIG. 3 illustrates a graphical representation of non-linear correction according to at least one example embodiment.

FIG. 4A illustrates a pictorial representation of example use cases in a physical space according to at least one example embodiment.

FIG. 4B illustrates a pictorial representation of a tiled view of coordinates within a portion of the physical space according to at least one example embodiment.

FIG. 5A illustrates a pictorial representation of first technique for system calibration according to at least one example embodiment.

FIG. 5B illustrates a pictorial representation of second technique for system calibration according to at least one example embodiment.

FIG. 5C illustrates a pictorial representation of third technique for system calibration according to at least one example embodiment.

FIG. 6A illustrates a pictorial representation of determining a distance according to at least one example embodiment.

FIG. 6B illustrates a pictorial representation of determining a dimension according to at least one example embodiment.

FIG. 6C illustrates a pictorial representation of determining a dimension according to at least one example embodiment.

FIG. 7 illustrates a block diagram of a machine learning model according to at least one example embodiment.

FIG. 8 illustrates a block diagram of a signal flow for triggering an application according to at least one example embodiment.

FIG. 9 illustrates a pictorial representation of a tiled view of coordinates and a pointing ray within a portion of a physical space according to at least one example embodiment.

FIG. 10 is a flowchart of a method for initiating a smart device action based on location according to at least one example embodiment.

FIG. 11 is a flowchart for measuring a length according to at least one example embodiment.

FIG. 12 shows an example of a computer device and a mobile computer device according to at least one example embodiment.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment and should not be interpreted as defining or limiting the range of values or properties encompassed by example embodiments. For example, layers, regions and/or structural elements may be reduced or exaggerated for clarity. The use of similar or identical reference numbers in the various drawings is intended to indicate the presence of a similar or identical element or feature.

### DETAILED DESCRIPTION

Smart devices have become ambient assistants within the home and other physical spaces. With a voice query, a user can cause a smart device to trigger an operation of the smart device without physical interaction. However, a voice interaction does not contain spatial context. For example, a queried smart device cannot accurately determine where in the physical space the query is coming from and the smart device doesn't have localization properties (e.g. a voice interaction proximate to two smart devices can cause both smart devices to respond).

Current solutions to this problem can include having the user verbally specify intent during query (e.g., specifying unique names for each smart device). However, current solutions can increase interaction time unnecessarily and cause user experience issues (e.g., the need to name and remember the names of smart devices). In addition, voice as an interaction tool works well when the device is in the same room as the user but does not work well in a whole home use scenario. Therefore, embodiments can include a system that can enable any wearable device or pseudo-wearable device (e.g., a mobile phone or a remote controller) as a controller having a few centimeter accurate, spatially-tagged, physical space controller that can enable ultrafast application triggers for any smart device.

Example implementations can include the use of an ultra-wideband (UWB) radio technology as a low energy, short-range, high-bandwidth communications tool. The technique can include the use of a UWB anchor (hereinafter anchor) and a UWB tag (hereinafter tag) to indicate a user's position within a physical space (e.g., a house, a room, and the like). With the knowledge of the user's position, spatial context and localization can be determined. The spatial context and localization can be used together with user interaction to cause a smart device to perform an action (e.g., home assistant response, turn lights on/off, lock/unlock doors, and the like). For example, example implementations can enable a smart device to classify, for example, a user input in a kitchen as turning on kitchen lights and the same input near an entrance as locking the door, within the physical space. Such an ambient interaction tool can decrease the time it takes to convert a user's intent to an action and can lead to a much more seamless user experience.

Determining a user's position can include determining a distance between the tag and the anchor. Therefore, example implementations can include using the determined distance for applications other than for determining spatial context and localization. The ability to electronically or digitally measure lengths and/or the physical dimensions of objects only using smart devices and without an explicit measuring tape has many applications in, for example, home furnishing, augmented reality, etc. For example, the determined distance can be used to measure the dimensions of an object (e.g., a desk, a chair, and the like). The determined distance can be used to measure the distance between two (or more) objects (e.g., the distance between a wall and a piece of furniture).

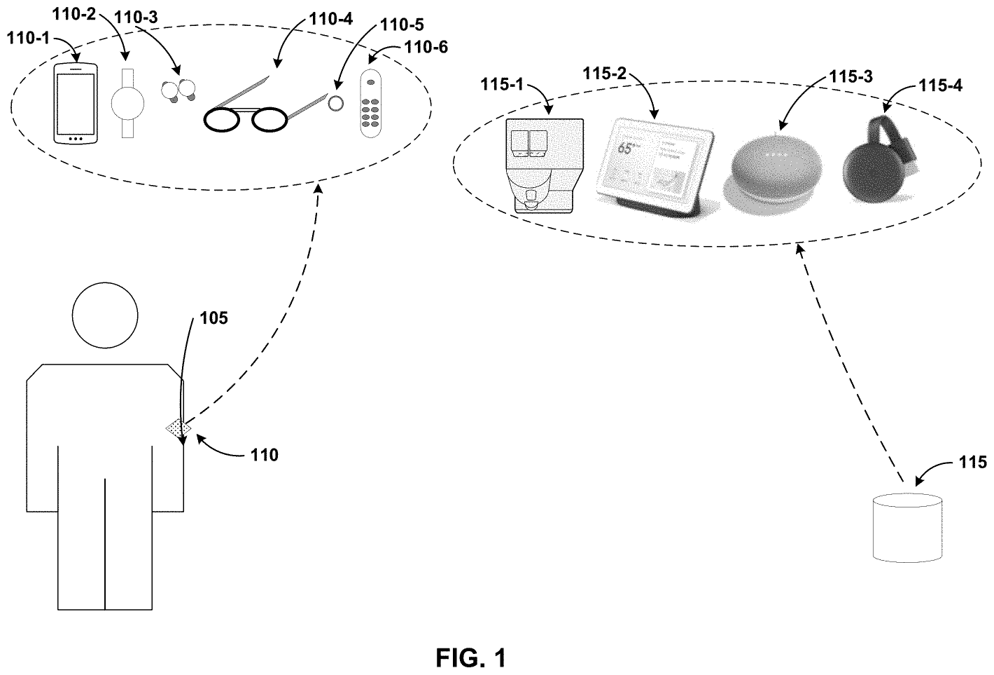

Existing techniques to achieve digital measurements use visual structure-from-motion (SfM), where a user takes a smartphone, points to the scene and moves around to reconstruct a proxy depth measurement. The user can then select two points in the phone screen view for the phone to compute distance using the reconstructed 3D mesh. The existing approach is limited in that it would not work well for a non-patterned surface where the parallax effect in moving smartphone cameras from one position to another will be relatively unseen. Therefore, systems using the existing approach typically add a disclaimer for the user to not take the measurement results literally and to expect +/−10-centimeter measurement accuracy. Example implementations that use a UWB enabled anchor and tag can achieve a displacement resolution (e.g., measurement accuracy) of a few centimeters. FIG. 1 is used to illustrate possible devices for use as an anchor and a tag.

As discussed above, UWB is a short-range, low power wireless communication protocol that operates through radio waves. Therefore, utilizing UWB over other signal standards (e.g., infra-red (IR), blue-tooth WIFI, and the like) is desirable for use in limited power storage devices (e.g., augmented reality (AR) glasses, smart glasses, smart watches, smart rings, and/or the like) because UWB is a low power wireless communication protocol. Further, UWB signals can pass through barriers (e.g., walls) and objects (e.g., furniture) making UWB far superior for use in controllers and other smart devices, because some other controller standards (e.g., IR) are line of sight and cannot generate signals that pass through barriers and objects

FIG. 1 illustrates a pictorial representation of a system for determining user position, spatial context and localization according to at least one example embodiment. As shown in FIG. 1 a system can include a user 105, a tag 110 and an anchor 115. The tag 110 can be a device (e.g., a mobile device) in possession of the user 105. For example, the tag 110 can be a mobile phone 110-1, a watch 110-2, ear buds 110-3, smart glasses 110-4, a smart ring 110-5, a remote control 110-6, and/or the like. The anchor 115 can be a device (e.g., a stationary device) in a fixed location within a physical space. For example, the anchor 115 can be an appliance 115-1, a video home assistant 115-2, an audio home assistant 115-3, a casting device 115-4, and/or the like. The tag 110 and the anchor 115 can be in substantially consistent communication using a UWB communications interface. The tag 110 in communication with the anchor 115 can form a spatially-aware controller.

Example implementations can utilize a UWB localization protocol to build a controller logic. Any static home device with a UWB chip can be used as the anchor and any commonly used wearable with a UWB chip can be used as the tag. Example implementations can use a human-computer interaction language (e.g. double-click, drag-and-drop) beyond a desktop and to physical objects in a physical space to enable a user to control lights, TV, and many other legacy smart devices not compatible with UWB with natural point-and-click control. Example implementations can operate using a single anchor device, compared to conventional localization methods which require installing multiple tag devices in a room for time difference of arrival (TDOA) trilateration. Machine learning software can be installed on the anchor-tag range-angle bundle to enable the sparsity of anchor devices.

Example implementations can store information associated with both the physical space of interaction and a pointed at smart device. This can enable unconventional applications of a single device storing and implementing multiple interactions depending on where the user is located. In addition to solving the localization problem, example implementations can solve the fast controller problem of using the wearable (UWB tag) as a quick air gesture device and saves intent-to-action time. This is possible due to the few-cm displacement resolution achieved by first-party, custom tracking software.

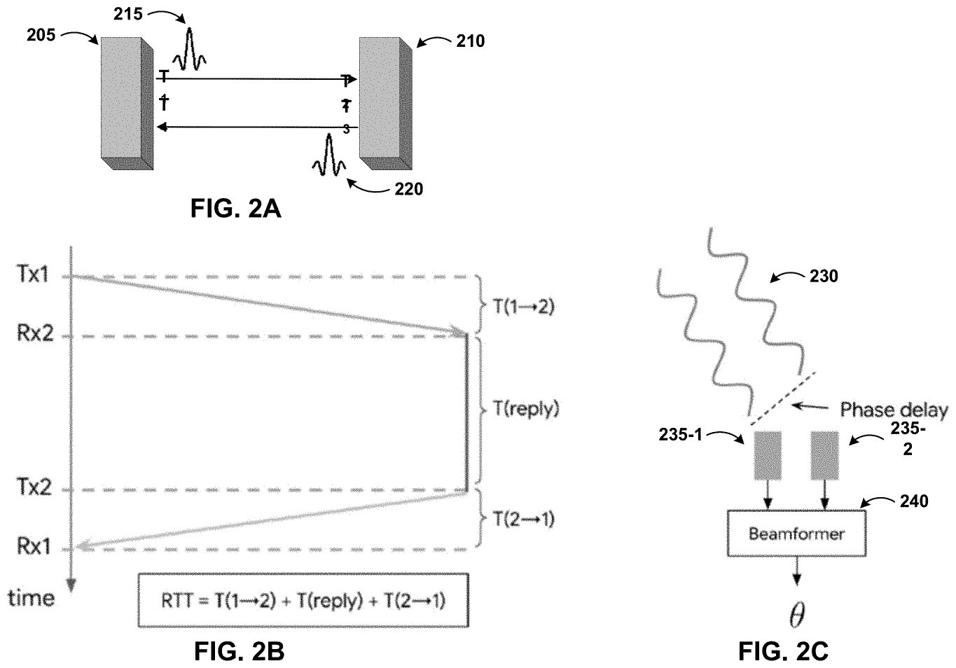

Example implementations can use a trained machine learning model (e.g., a convolutional autoencoder) for accurate UWB localization results in the physical space with sparse hardware and beyond-trajectory inputs (e.g. including RSSI) to network. UWB data can be fused with on-tag-device motion sensors such as an Inertial Measurement Unit (IMU) through fusion training to enable low-variance translational tracking. Example implementations can ensure a net operating power budget meets wearable/phone battery life constraint using gated classification. FIGS. 2A-2C can be used to illustrate determining UWB ranging and angle-of-arrival which can be used in determining a distance between an anchor and a tag.

FIG. 2A illustrates a block diagram of signals communicated between an anchor and a tag according to at least one example embodiment. As shown in FIG. 2A, an anchor 205 can communicate a signal 215 at time T₁. At time T₂, the signal 215 is received by tag 210. In response to receiving signal 215, at time T₃ the tag 210 can communicate a signal 220 to anchor 205. At time T₄, the signal 220 is received by the anchor 205. FIG. 2B can illustrate the signal flow shown in FIG. 2A the signal flow can be used in ranging (e.g., determining distance).

FIG. 2B illustrates a graphical diagram of ranging according to at least one example embodiment. As shown in FIG. 2B at time T×1 a signal (e.g., signal 215) is communicated (e.g., from the anchor 205 to the tag 210). The signal can be a coded signal (e.g., including some information associated with the anchor. At time R×2 the signal (e.g., signal 215) is received (e.g., by tag 210). The communication has a time delay T(1-2). At time T×2 a signal (e.g., signal 220) is communicated (e.g., from the tag 210 to the anchor 205). In addition, there is a time delay T (reply) between receiving the signal (e.g., signal 215) at time R×2 and communicating the signal (e.g., signal 220) at time T×2. The time delay can be a fixed time delay and the signal (e.g., signal 220) can be a reply pulse that is generated (e.g., by the tag 210) during the time delay.

The total time delay (RTT) can be calculated (e.g., by the anchor) as:

RTT=T(1→2)+T(reply)+T(2→1) (1)

The distance (r) between the anchor (e.g., anchor 205) and the tag (e.g. tag 210) can be calculated using total delay (RTT) as:

$$r = \frac{c \times ( RTT - {T}_{reply} )}{2} \qquad ( 2 )$$

where c is the speed of light.

Should the anchor (e.g., anchor 205) and/or the tag (e.g., tag 210) have multiple antennas (e.g., two antennas), UWB can be used to determine an angle-of-arrival (AoA) of a pulse by comparing phase shifts over multiple antennas using beamforming techniques. FIG. 2C illustrates a block diagram of determining an AoA according to at least one example embodiment. As shown in FIG. 2C, a UWB system can include 1×2 antennas 235-1, 235-2 in an anchor (e.g., anchor 205) and 1×2 antennas (not shown) in a tag (e.g., tag 210) communicating a signal 230. A beamformer 240 can generate an angle θ (based on a phase delay). Three unique values (e.g., range-angle data) can be determined (e.g., calculated). First, the distance (r) can be calculated (as described above referencing FIG. 2B). Second, the AoA of the tag in the anchor's reference in the horizontal plane (θ) can be determined. Third, AoA of the anchor in the anchor's reference in the horizontal plane (ϕ) can be determined. Additional angles could be resolved with three or more antennas.

The range-angle data obtained from a single UWB frame can be transformed into cartesian coordinates. This allows the range-angle data bundle to have full information indicating where the tag (e.g., tag 210) is located and the direction the tag is pointing (assuming the position of the antennas in the tag indicate the direction). Formatting the data into cartesian coordinates can enable direct thresholding or applying decision trees on the bundle of range-angle data and can enable defining a virtual box/circle, which is guided by natural distance metrics. By contrast, doing the same in the raw (r, θ, ϕ) polar coordinates, techniques may be limited with asymmetric cone decision boundaries. Formatting the range-angle data into the cartesian coordinate system can be computed as:

x=r·cos θ; y=r·sin θ; and BUNDLE={x,y,ϕ} (3)

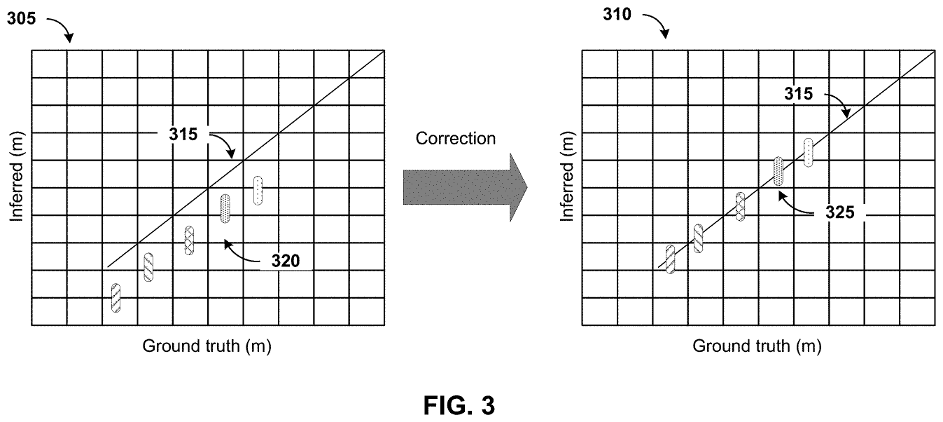

There can be an affine bias to the raw distance data generated (e.g., calculated, measured, and/or the like. Therefore, the data may be corrected as described with regard to FIG. 3.

FIG. 3 illustrates a graphical representation of non-linear correction according to at least one example embodiment. As shown in FIG. 1, a first graph 305 has data 320 (e.g., raw distance data) and a straight line 315 representing the ideal values for the distance data. A non-linear correction (described in more detail below) can be applied to the data 320 (e.g., raw distance data) resulting in corrected data 325 as shown in a second graph 310. The corrected data 325 is shown along the straight line 315 representing the ideal values for the distance data.

Correction can include applying a non-linear correction to the data 320 (e.g., raw distance data) by performing a polynomial regression during runtime (e.g., as the anchor calculates distance based on time). The regressor model can be trained on calibration datasets that can be collected offline (e.g., a factory setting, a production setting, and/or the like). Raw UWB data can be noisy. Therefore, trajectory filtering can be applied to smooth the raw data. For example, a Kalman filter can be used to filter the raw data because, with a Kalman filter, Gaussian channel noise can be consistent with (or similar to) UWB sensor noise characteristics.

Other distance-dependent noise variables could be included in the regressor model by using a variant like the RSSI-aware Kalman filter. An additional training with a convolutional denoising model, while taking a small computational hit for improved accuracy from fusion can be done. The convolutional model can be flexible in that the convolutional model can support input integration from supplementary received signal strength indication (RSSI) readings or an optional Inertial Measurement Unit (IMU).

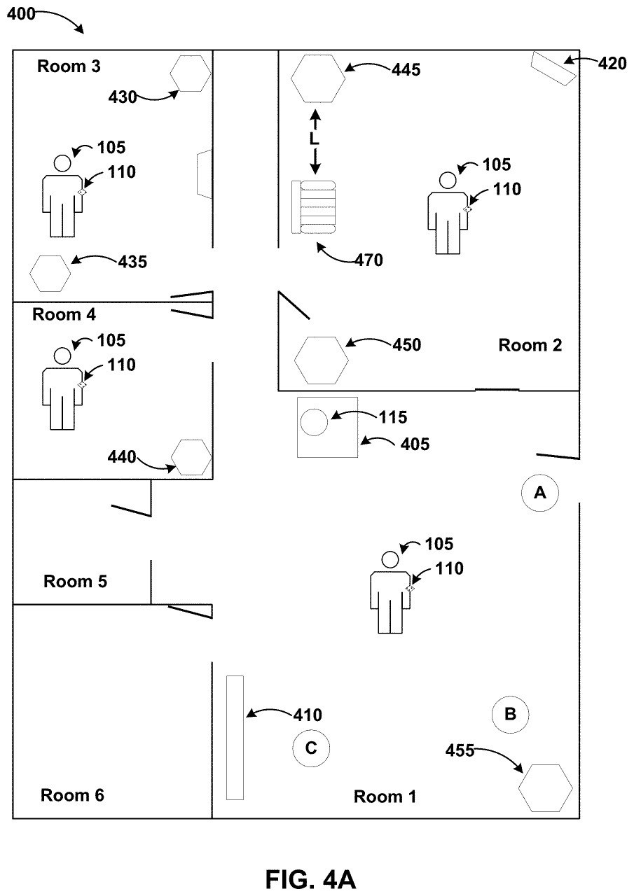

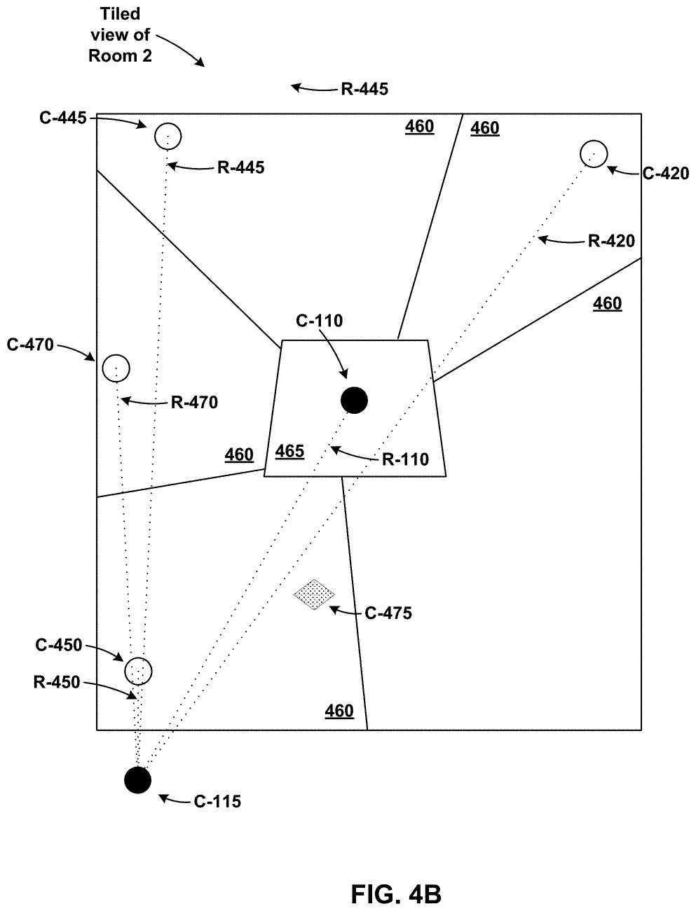

FIG. 4A is used to describe some possible use cases for causing a smart device to perform an action using spatial context and localization data generated using UWB communications (e.g., using a spatially-aware controller). FIG. 4A illustrates a pictorial representation of example use cases according to at least one example embodiment. As shown in FIG. 4A a physical space 400 can include a plurality of rooms (e.g., room 1, room 2, room 3, room 4, room 5, and room 6). A user 105 can be carrying a tag 110 and the physical space 400 can include an anchor 115 (shown in room 1 on furniture 405). The anchor 115 together with the tag 110 can form a spatially-aware controller.

The user 105 with the tag 110 can cause a smart device to perform an action based on a room the user is in, the users position within a room and/or a gesture or voice command. For example, within room 1, the user 105 could be at position A, position B or position C. Position A is proximate to a door (e.g., to outside the physical space 400). The door can include a smart device configured to lock or unlock the door based on the state (locked or unlocked) of the door. While at position A, the user 105 could make a gesture (e.g., wave a hand from side-to-side) or call out a verbal command. The spatially-aware controller (e.g., the combination of anchor 115 together with the tag 110) could determine the user is at position A within room 1. Based on this location, the gesture or verbal command, and a state of the door the spatially-aware controller could cause the door to lock or unlock (e.g., the action).

Position B is proximate to a light fixture 455 (e.g., as a smart device). The light fixture 455 can be (or include) a smart device configured to turn a light on or off based on the state (on or off) of the light of the light fixture 455. While at position B, the user 105 could make a gesture (e.g., wave a hand from side-to-side) or call out a verbal command. The spatially-aware controller (e.g., the combination of anchor 115 together with the tag 110) could determine the user is at position B within room 1. Based on this location, the gesture or verbal command, and a state of the door the spatially-aware controller could cause the light fixture 455 to turn on or off (e.g., the action). Position C is proximate to a television 410 (e.g., as a smart device). The television 410 can be (or include) a smart device configured to perform an action associated with a television (e.g., change/select channel, select input, change volume, select a program, and/or the like. While at position C, the user 105 could make a gesture (e.g., wave a hand from side-to-side, up or down, and/or the like) or call out a verbal command. The spatially-aware controller (e.g., the combination of anchor 115 together with the tag 110) could determine the user is at position C within room 1. Based on this location, the gesture or verbal command, and a state of the door the spatially-aware controller could cause the light fixture to change a channel (e.g., the action) of the television 410.

Room 2 of the physical space 400 can include a home assistant 420 and light fixtures 445 and 450. The light fixtures 445 and 450 can be (or include) a smart device configured to turn a light on or off based on the state (on or off) of the light of the light fixtures 445 and 450. Room 3 of the physical space 400 can include a home assistant 425 and light fixtures 430 and 435. The light fixtures 430 and 435 can be (or include) a smart device configured to turn a light on or off based on the state (on or off) of the light of the light fixtures 430 and 435. The home assistant 420 and the home assistant 425 may be proximate to each other such that a verbal command can be received (e.g., heard) by both the home assistant 420 and the home assistant 425. Therefore, both the home assistant 420 and the home assistant 425 could initiate an action based on a voice command when a user only intended one of the home assistant 420 and the home assistant 425 to initiate the action.

The spatially-aware controller (e.g., the combination of anchor 115 together with the tag 110) could determine the user is at position within the physical space (e.g., room 2 or room 3). Therefore, should the user 105 be at a location within room 2 and call out a voice command (e.g., lights on), the spatially-aware controller can determine the user 105 is within room 2. In response to determining the user 105 is within room 2, the spatially-aware controller can cause the home assistant 420 (and not home assistant 425) to initiate an action based on the voice command (e.g., turn the lights associated with light fixtures 445 and 450 on). Should the user 105 be at a location within room 3 and call out a voice command (e.g., lights on), the spatially-aware controller can determine the user 105 is within room 3. In response to determining the user 105 is within room 3, the spatially-aware controller can cause the home assistant 425 (and not home assistant 420) to initiate an action based on the voice command (e.g., turn the lights associated with light fixtures 430 and 435 on).

Room 4 of the physical space 400 can include a light fixture 440. The light fixture 440 can be (or include) a smart device configured to turn a light on or off based on the state (on or off) of the light of the light fixture 440. In addition, the light fixture can be responsive to user location and/or user gestures. For example, user 105 entering into room 4 can cause the light of the fixture 440 to turn on (should the light state be off) because light fixture 440 is responsive to the location of the tag 110 of the spatially-aware controller. The user 105 in room 4 can cause the light of the fixture 440 to turn off (should the light state be on) with a gesture (e.g., causing the tag 110 to move) while the user is in room 4 (e.g., as determined by the spatially-aware controller). In other words, the spatially-aware controller can determine the user is within room 4 and that the user has caused tag 110 to move in a pattern indicating a gesture. The spatially-aware controller can cause the light fixture to turn off (e.g., the action) in response to the spatially-aware controller determining the user has made the gesture within room 4.

Room 4, room 5 and room 6 do not include a home assistant. Therefore, should user 105 call out a voice command, no action may be triggered. For example, the spatially-aware controller can determine that the user is in room 4, room 5, or room 6 when home assistant 420 and/or home assistant 425 receive (e.g., hear) the voice command. In response to the spatially-aware controller determining the user is in room 4, room 5, or room 6, the spatially-aware controller can cause home assistant 420 and/or home assistant 425 to not respond (e.g., ignore) the voice command.

Room 2 also includes a piece of furniture 470. The user 105 may desire to determine a distance associated with furniture 470. For example, the user 105 may desire to know the distance L between the furniture 470 and the light fixture 445. The user can use the tag 110 of the spatially-aware controller to determine the distance by moving the tag 110 from the furniture 470 to the light fixture 445. In response to causing the tag 110 to move from the furniture 470 to the light fixture 445, the anchor 115 of the spatially aware controller can determine the distance L. Further, the user 105 may desire to determine a distance associated with furniture 470. For example, the user 105 may desire to know a dimension associated with the furniture 470. The user can use the tag 110 of the spatially-aware controller to determine, for example, the height, width, and/or length of the furniture 470 by moving the tag 110 over the furniture 470 in a pattern based on the dimensions. In response to causing the tag 110 to move in a pattern based on the dimensions, the anchor 115 of the spatially aware controller can determine the dimensions (e.g., height, width, and/or length) of the furniture 470.

Other spatially aware actions based on a location of the tag 110 of the spatially-aware controller are within the scope of this disclosure. Further, other measurements can be made using the tag 110 of the spatially-aware controller are within the scope of this disclosure. Example implementations can include generating a tiled (e.g., tessellation) view of coordinates within the physical space (or a portion thereof). FIG. 4B can be used to describe a tiled (e.g., tessellation) view of coordinates within a portion (e.g., room 2) of the physical space 400.

FIG. 4B illustrates a pictorial representation of a tiled view of coordinates within a portion of the physical space according to at least one example embodiment. As shown in FIG. 4B, coordinate C-115 represents coordinates associated with the anchor 115. Note: as shown in FIG. 4A, the anchor 115 is external to room 2. Therefore, coordinate C-115 is illustrated external to the tiled view of room 2 in FIG. 4B. Tiles 460, 465 each include one coordinate associated with room 2. The coordinates can be based on UWB range and angle data (e.g., captured during a calibration process described below). The UWB range and angle data can be stored (e.g., in a database) in association with the anchor 115 and/or the tag 110. During use (e.g., a runtime operation) of the spatially-aware controller, the UWB range and angle data can be can be retrieved (e.g., read from the database), formatted in a 2D (e.g., cartesian) coordinate system, and used to generate the tiled view (e.g., of room 2).

For example, generating a tiled (e.g., tessellation) view of coordinates can include applying a Euclidean distance metric to Voronoi-tessellate the space The tessellated space can be used when determining proximity to a location (e.g., coordinate) of interest (e.g., the calibrated locations). Tessellation can create tiles, a mesh, a set of connected geometric shapes, and the like that can represent the physical space 400 and the zones (e.g., rooms and objects) of the physical space 400. Tessellation can cause the two-dimensional (2D) space to appear as a three-dimensional (3D) representation of the physical space 400.

Coordinate C-110, coordinate C-420, coordinate C-445, coordinate C-450, and coordinate C-470 each can represent a location of the tag 110, the home assistant 420, the light fixtures 445 and 450, and the furniture 470, respectively, within room 2. A closed circle (or filled in circle) can represent a location without an object. An open circle can represent a location with an object. A Ray R-110, ray R-420, ray R-445, ray R-450, and ray R-470 (illustrated as dotted lines) each can represent a signal path between the anchor 115 and the tag 110 at a time when the tag 110 was located at the illustrated location and in communication with (e.g., during a calibration operation) the anchor 115.

In an example implementation, generating the tiled (e.g., tessellation) view of coordinates within the physical space can include boundaries based on defined portions (e.g., rooms) of the physical space. While the spatially-aware controller (e.g., tag 110) is in use (e.g., during a runtime operation), a user in possession of the spatially-aware controller can be anywhere, for example, within the physical space 400. Determining the location of the user can be based on which tile the user is in. For example, tile 465 can be associated with room 2 (e.g., in the aforementioned database), and any tile adjacent (in contact with virtually) to tile 465 (e.g., tiles 460) can be identified as within room 2. Therefore, if a coordinate currently associated the spatially-aware controller (e.g., tag 110) is in one of tiles 460, 465, the user 105 can be identified as being within room 2. For example, coordinate C-475 can be a coordinate based on a current location of the spatially-aware controller (in possession of the user 105). Therefore, the user 105 can be identified as being (or determined to be) within room 2.

In an example implementation, the location of a user in possession of a spatially-aware controller can be determined using a trained ML model. Therefore, the ML model can be trained to determine the location of a user based on a tile associated with a room (e.g., tile 465) and tiles adjacent to tile associated with a room (e.g., tiles 460).

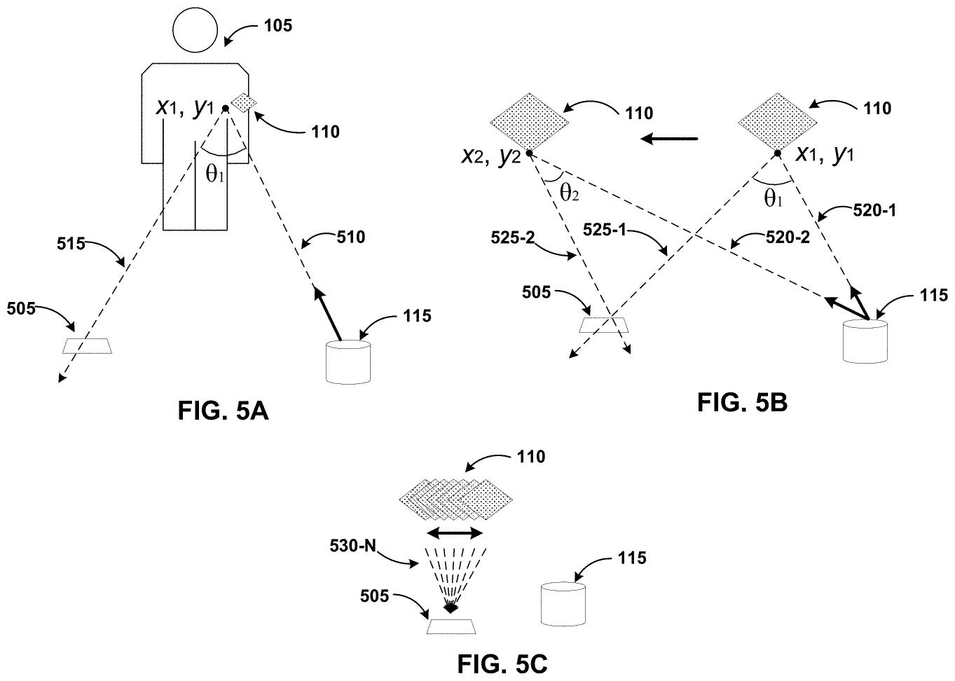

FIGS. 5A, 5B, and 5C describe calibration techniques that can be used to enable the spatially-aware controller to make accurate location determinations and/or measurements (e.g., distance and/or length measurements). For applications that use spatial memory, the user (e.g., user 105) performing a calibration operation can be used to determine the relevant coordinates (e.g. at least one coordinate defines room 1, at least one coordinate defines position A within room 1, at least one coordinate defines room 2, and the like) in a physical space (e.g., physical space 400) that can define locations of relevance (e.g., rooms, devices, and/or the like). In an example implementation, the calibration can be a one-click-per-zone technique (described with regard to FIG. 5A). During runtime, a trained ML model can be used to determine whether the user is near at least one of these predefined (e.g., through the calibration process) coordinates.

FIG. 5A illustrates a pictorial representation of a first technique for system calibration according to at least one example embodiment. The first technique can be a one-click or one-click per zone technique. As shown in FIG. 5A, the user 105 having tag 110 can be in a location (e.g., room 2) with the tag positioned at coordinates x₁, y₁. The coordinates x₁, y₁ can be determined based on signal 510 using the distance calculations based on signal times described above. During the calibration process coordinates x₁, y₁ can be associated with the location (e.g., room 2). Associating coordinates with a location can be a manual process (e.g., through operation of a user interface supporting database entry).

The one-click technique can also be used during calibration to identify smart devices controllable when the user is at a location. For example, the tag 110 can be pointed at a smart device 505 (e.g., a home assistant). This can infer a line 515 at an angle θ from the signal 510. The line 515 can be used to identify any device (e.g., smart device 505) along the line 515. In other words, if more than one device is located along the line 515, each of the devices can be identified as controllable when the user (e.g., user 105) is in the location (e.g., associated with x₁, y₁), and/or when pointing the tag (e.g., tag 110) at the angle θ.

However, the one-click technique may only diversify controls over space, not a pointing direction towards a particular device. In other words, for a single click (e.g., using the one-click-per-zone technique), the generated calibration bundle has a line ambiguity (e.g., line 515 can be ambiguous or intersect more than one smart device) that does not necessarily resolve the point location of the smart device to be controlled. For example, in universal controller applications, that can enable point-and-control for a smart device, the one-click calibration technique may be insufficient. Therefore, the one-click-per calibration technique can be extended into an N-click calibration technique (described with regard to FIG. 5B).

FIG. 5B illustrates a pictorial representation of second technique for system calibration according to at least one example embodiment. The second technique can be a N-click or N-click per smart device technique. As shown in FIG. 5B, the tag 110 (illustrated without the user 105 for clarity) can be in a location (e.g., room 2) with the tag positioned at coordinates x₁, y₁. The coordinates x₁, y₁ can be determined based on signal 520-1 using the distance calculations based on signal times described above. During the calibration process coordinates x₁, y₁ can be associated with the location (e.g., room 2). Associating coordinates with a location can be a manual process (e.g., through operation of a user interface supporting database entry).

The tag 110 can be moved within the location (e.g., room 2) to coordinates x₂, y₂. The coordinates x₂, y₂ can be determined based on signal 520-2 using the distance calculations based on signal times described above. During the calibration process coordinates x₂, y₂ can be associated with the location (e.g., room 2). Associating coordinates with a location can be a manual process (e.g., through operation of a user interface supporting database entry). The tag 110 can be moved within the location (e.g., room 2) N times.

The N-click technique can also be used during calibration to identify smart devices controllable when the user is at a location. For example, the tag 110 can be pointed at a smart device 505 (e.g., a home assistant) when at coordinates x₁, y₁ and at coordinates x₂, y₂. Line 525-1 can be inferred at an angle Ni from the signal 520-1. Line 525-2 can be inferred at an angle θ₂ from the signal 520-2. The intersection of lines 525-1 and 525-2 can be used to identify any device (e.g., smart device 505). In other words, one device located at the intersection of lines 525-1 and 525-2 can be identified as controllable when the user (e.g., user 105) is in the location (e.g., associated with coordinates x₁, y₁ and/or coordinates x₂, y₂), and/or when pointing the tag (e.g., tag 110) at the angle θ₁, θ₂, or an equivalent angle should the tag be proximate (e.g., in room 2) but not at coordinates x₁, y₁ or coordinates x₂, y₂.

Mathematically, the N-click technique identifying a single smart device can be expressed as:

|∩ₖ₌₁^{N} [symbol] (BUNDLEₖ)|=1, (4)

whereas the one-click technique identifying more than one smart device can be expressed as:

| [symbol] (BUNDLE₁)|=+∞, (5)

where BUNDLE is the cartesian coordinate data bundle (see eqn. 4).

This N-click technique can be performed once for a setup (e.g., an anchor/tag combination or spatially-aware controller) and thus can be an operation within a system use flow (e.g., an initial setup operation). Using the device position (stored cartesian coordinate x, y for the device) determined using the calibration, a universal controller application can check if an epsilon-ball function around this position (this is for noise tolerance) intersects with the runtime bundle line set to determine whether the user (e.g., user 105) is pointing to a smart device (e.g., smart device 505) and indicates the user is interacting with the smart device. The function can be expressed as:

1(| [symbol] (x_{device}y_{device},∈)∩ [symbol] (BUNDLE)|>0). (6)

Another calibration technique can be to have the user (e.g., user 105) to walk around with or without a tag (e.g., tag 110) pointed to target smart device. Functionally, this can be a high-N click calibration technique (described with regard to FIG. 5C). The high-N click technique can satisfy the unique point condition (e.g., not an ambiguous line that can intersect more than one smart device) in a noiseless scenario.

FIG. 5C illustrates a pictorial representation of third technique for system calibration according to at least one example embodiment. The third technique can be a high N-click or high N-click per smart device technique. As shown in FIG. 5C, the tag 110 (illustrated without the user 105 for clarity) can be moved about in a location (e.g., room 2). During the calibration process coordinates can be associated with the location (e.g., room 2) as described above with regard to the N-click technique. Associating coordinates with a location can be a manual process (e.g., through operation of a user interface supporting database entry).

The high N-click technique can also be used during calibration to identify smart devices controllable when the user is at a location. For example, the tag 110 can be pointed at a smart device 505 (e.g., a home assistant) while moving about. Lines 530-N can be inferred based on the movement of the tag 110. The intersection of lines 530-N can be used to identify any device (e.g., smart device 505). In other words, one device located at the intersection of lines 525-N can be identified as controllable when the user (e.g., user 105) is in the location, and/or when pointing the tag (e.g., tag 110) at the smart device (e.g., smart device 505).

For noisy pointing vectors, the device can be located at a fan-calibration point. The fan-calibration point can be computed using a least-squares optimization over the projection error sum as:

$${}_{x}^{minimize} {\sum }_{i = 0}^{n - 1} {‖ x - {proj}_{ℓ i} ( x ) ‖}_{2}^{2} \qquad ( 7 )$$

Expanding the cost term can indicate that this function is convex as it is a sum of quadratics.

$$\begin{matrix}ℒ ( x ) = {\sum }_{i = 0}^{n - 1} {‖ x - {proj}_{ℓ i} ( x ) ‖}_{2}^{2} \\ = {\sum }_{i = 0}^{n - 1} {‖ x - [ {P}_{i} x + ( I - {P}_{i} ) {x}_{i} ] ‖}_{2}^{2} \\ = {\sum }_{i = 0}^{n - 1} {‖ ( I - {P}_{i} ) ( x - {x}_{i} ) ‖}_{2}^{2}\end{matrix} \qquad ( 8 )$$

By forcing the zero-gradient condition, the closed-form optimal solution can be solved, which is computationally dominated by one matrix inversion that can be applied during runtime as:

\hat{x}_{LS}=(Σᵢ₌₀ⁿ⁻¹(I−Pᵢ)^{T}(I−Pᵢ))⁻¹(Σᵢ₌₀ⁿ⁻¹(I−Pᵢ)^{T}(I−Pᵢ)xᵢ). (9)

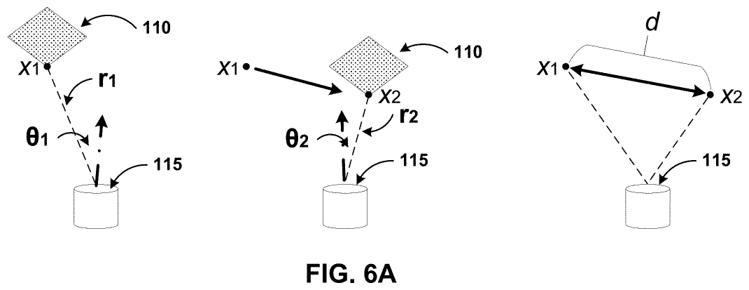

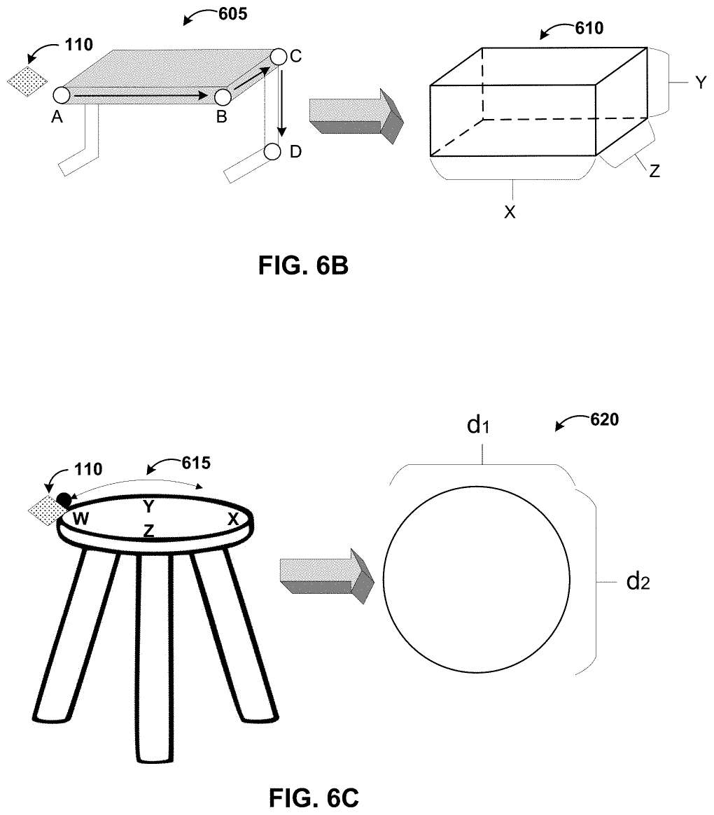

For three-dimension (3D) controls using a 3-antenna UWB module, N should be at least 3 instead of 2 as used above. As briefly discussed above, the user can use the tag 110 of the spatially-aware controller to determine measurements including, for example, length by moving the tag 110 between two points and object dimensions by moving the tag 110 over the object in a pattern based on the dimensions. Example implementations can be used to measure dimensions to centimeter accuracy by using UWB ranging as discussed above. UWB ranging can allow accurate distance measurement between the UWB anchor (e.g., anchor 115) and UWB tag (e.g., tag 110). FIG. 6A is used to describe using a UWB system (e.g., an anchor and a tag(s)) or spatially-aware controller for digital measurements.

FIG. 6A illustrates a pictorial representation of determining a distance according to at least one example embodiment. As shown in FIG. 6A, anchor 115 and tag 110 are used by a user (e.g., user 105, not shown for clarity) to make digital measurements. The user can pass the tag over the path that the user wants to make the distance measurement over. For example, the tag 110 is placed (e.g., through user motion) in a first position X₁ (e.g., on a first side of a distance to be measured). The tag 110 is then placed (e.g., through user motion) in a second position X₂ (e.g., on a second side of a distance to be measured). A range and angle can be determined (as discussed above) at positions X₁ and X₂. The ranges r₁, r₂ and angles θ₁, θ₂ can be used (as discussed above and below) to determine cartesian coordinates. The cartesian coordinates for X₁ and X₂ can be used to determine (e.g., calculated using a trigonometric equation) the distance d as the length to be measured. The start and end of the user motion can be stored by user input (e.g. click on the tag (e.g., as a smart watch or mobile phone) touch screen user interface). Cartesian coordinates can be calculated (similar to developing eqn. 3) based on the ranges r and angles θ as:

x₁=r₁·cos θ₁; y₁=r₁·sin θ₁; x₂=r₂·cos θ₂; and y₂=r₂·sin θ₂. (10)

Then the distance d can be determined as the Euclidean norm of the difference in coordinates as:

∥(x₁,y₁)−(x₂,y₂)∥ (11)

In an example implementation, the N-click calibration technique (described above with regard to FIG. 5B) can be used to calibrate the anchor 115 and tag 110 digital measurement system prior to making digital measurements. For example, the N-click calibration technique can be performed with N=two (2) making the calibration technique a two-click calibration technique. FIGS. 6B and 6C describe using the spatially-aware controller (e.g., the anchor 115 and tag 110) to measure dimensions of an object.

FIG. 6B illustrates a pictorial representation of determining a dimension according to at least one example embodiment. As shown in FIG. 6B, a desk 605 (as an object to measure) can be geometrically represented as a box 610. Measuring the desk 605 can include measuring three distances. The distance from point A to point B, the distance from point B to point C, and the distance from point C to point D should be measured.

To measure the distance from point A to point B the tag 110 can be placed at point A and a range r_{A} from anchor 115 (not shown for clarity) and an angle θ_{A} associated with the direction of a signal to point A from anchor 115 can be determined by the spatially-aware controller (e.g., the anchor 115). Then, the tag 110 can be placed at point B and a range r_{B} from anchor 115 and an angle θ_{B} associated with the direction of a signal to point B from anchor 115 can be determined by the spatially-aware controller (e.g., the anchor 115). Cartesian coordinates can be calculated (as discussed with regard to FIG. 6A) based on the ranges r and angles θ. Then the distance (or X of box 610) measurement can be determined as the Euclidean norm of the difference in coordinates (as discussed with regard to FIG. 6A).

To measure the distance from point B to point C the tag 110 can be placed at point B and a range r_{B} from anchor 115 and an angle θ_{B} associated with the direction of a signal to point B from anchor 115 can be determined by the spatially-aware controller (e.g., the anchor 115). Then, the tag 110 can be placed at point C and a range r_{C} from anchor 115 and an angle θ_{C} associated with the direction of a signal to point C from anchor 115 can be determined by the spatially-aware controller (e.g., the anchor 115). Cartesian coordinates can be calculated (as discussed with regard to FIG. 6A) based on the ranges r and angles θ. Then the distance (or Y of box 610) measurement can be determined as the Euclidean norm of the difference in coordinates (as discussed with regard to FIG. 6A).

To measure the distance from point C to point D the tag 110 can be placed at point C and a range r_{C} from anchor 115 and an angle θ_{C} associated with the direction of a signal to point C from anchor 115 can be determined by the spatially-aware controller (e.g., the anchor 115). Then, the tag 110 can be placed at point D and a range r_{D} from anchor 115 and an angle θ_{D} associated with the direction of a signal to point D from anchor 115 can be determined by the spatially-aware controller (e.g., the anchor 115). Cartesian coordinates can be calculated (as discussed with regard to FIG. 6A) based on the ranges r and angles θ. Then the distance (or Z of box 610) measurement can be determined as the Euclidean norm of the difference in coordinates (as discussed with regard to FIG. 6A).

FIG. 6C illustrates a pictorial representation of determining a dimension according to at least one example embodiment. As shown in FIG. 6C, a chair seat 615 (as an object to measure) can be geometrically represented as a circle 620. Measuring the chair seat 615 can include measuring two distances (e.g., as diameters). The distance from point W to point X and the distance from point Y to point Z should be measured.

To measure the distance from point W to point X (as diameter d₁) the tag 110 can be placed at point W and range r_{W} from anchor 115 (not shown for clarity) and an angle θ_{W} associated with the direction of a signal to point from anchor 115 can be determined by the spatially-aware controller (e.g., the anchor 115). Then, the tag 110 can be placed at point X and a range r_{X} from anchor 115 and an angle θ_{X} associated with the direction of a signal to point X from anchor 115 can be determined by the spatially-aware controller (e.g., the anchor 115). Cartesian coordinates can be calculated (as discussed with regard to FIG. 6A) based on the ranges r and angles θ. Then the distance (or d₁ of circle 620) measurement can be determined as the Euclidean norm of the difference in coordinates (as discussed with regard to FIG. 6A).

To measure the distance from point Y to point Z the tag 110 can be placed at point Y and a range r_{Y} from anchor 115 and an angle θ_{Y} associated with the direction of a signal to point Y from anchor 115 can be determined by the spatially-aware controller (e.g., the anchor 115). Then, the tag 110 can be placed at point Z and a range r_{Z} from anchor 115 and an angle θ_{Z} associated with the direction of a signal to point Z from anchor 115 can be determined by the spatially-aware controller (e.g., the anchor 115). Cartesian coordinates can be calculated (as discussed with regard to FIG. 6A) based on the ranges r and angles θ. Then the distance (or f₂ of circle 620) measurement can be determined as the Euclidean norm of the difference in coordinates (as discussed with regard to FIG. 6A).

Alternatively, the circumference of the circle 620 can be determined using a Riemann sum over a set of measurement data. The set of measurement data can be acquired by continually gesturing over the chair seat 615 with the tag 110. While gesturing over the chair seat 615, the spatially-aware controller (e.g., the anchor 115) can be collecting data (e.g., r and θ). Cartesian coordinates can be calculated, and the circumference can be calculated as:

Σₖ₌₂^{N}∥(xₖ₋₁,yₖ₋₁)−(xₖ,yₖ)∥₂ (12)

As discussed above, a machine learning (ML) model can be used to determine or help determine a location associated with a spatially-aware controller (e.g., a location of tag 110). ML models can include the use of algorithms including convolutional neural networks, recursive neural networks, decision trees, random forest, k-nearest neighbor and/or the like. For example, a convolutional neural network (CNN) can be used to match pixels, determine pixel positions, identify pixels, and/or the like. A CNN architecture can include an input layer, a feature extraction layer(s) and a classification layer(s).

An input can accept 2D data (e.g., cartesian coordinate data) and/or 3D data (e.g., x, y, z). A feature extraction layer(s) can include a convolutional layer(s) and a pooling layer(s). The convolutional layer(s) and the pooling layer(s) can find locations and progressively construct higher-order locations. An extraction layer(s) can be feature learning layers. Classification layer(s) can generate class probabilities or scores (e.g., indicating the likelihood of a location match).

Training (e.g., training the feature extraction layer(s)) can include, for example, supervised training and unsupervised training. Supervised training includes a target/outcome variable (e.g., a ground truth or dependent variable) to be predicted from a given set of predictors (independent variables). Using these set of variables, a function that can map inputs to desired outputs is generated. The training process continues until the model achieves a desired level of accuracy based on training data. Unsupervised training includes use of a machine learning algorithm to draw inferences from datasets consisting of input data without labeled responses. Unsupervised training sometimes includes clustering. Other types of training (e.g., hybrid and reinforcement) can also be used.

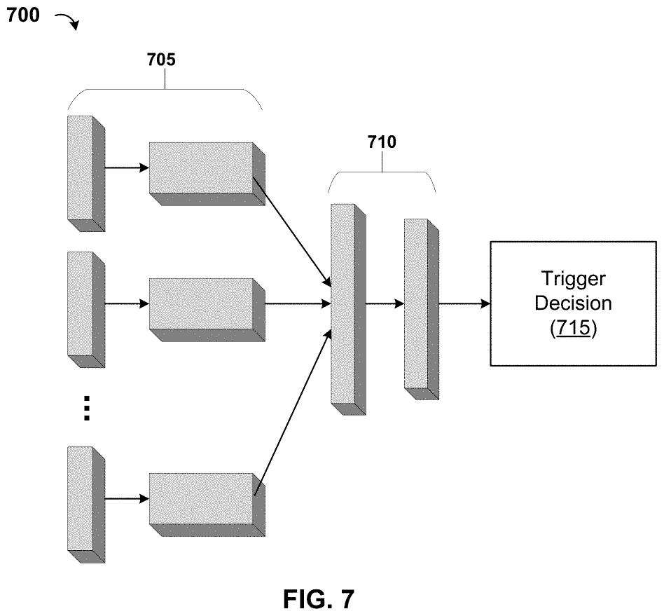

As mentioned above, the training of a ML model can continue until a desired level of accuracy is reached. Determination of the level of accuracy can include using a loss function. For example, loss functions can include hinge loss, logistic loss, negative log likelihood, and the like. Loss functions can be minimized to indicate a sufficient level of accuracy of the ML model training has been reached. Regularization can also be used. Regularization can prevent overfitting. Overfitting can be prevented by making weights and/or weight changes sufficiently small to prevent training (e.g., never ending) training. FIG. 7 is used to describe an example ML model.

FIG. 7 illustrates a block diagram of a machine learning (ML) model according to at least one example embodiment. As shown in FIG. 7, ML model 700 includes at least one convolution/pooling layer 705, at least one feature classification layer 710 and a trigger decision 715 block.

The at least one convolution/pooling layer 705 can be configured to extract features from data (e.g., cartesian coordinate data). Features can be based on x, y z coordinates and/or the like. A convolution can have a filter (sometimes called a kernel) and a stride. For example, a filter can be a 1×1 filter (or 1×1×n for a transformation to n output channels, a 1×1 filter is sometimes called a pointwise convolution) with a stride of 1 which results in an output of a cell generated based on a combination (e.g., addition, subtraction, multiplication, and/or the like) of the features of the cells of each channel at a position of the M×M grid. In other words, a feature map having more than one depth or channels is combined into a feature map having a single depth or channel. A filter can be a 3×₃ filter with a stride of 1 which results in an output with fewer cells each channel of the M×M grid or feature map. The output can have the same depth or number of channels (e.g., a 3×₃×n filter, where n=depth or number of channels, sometimes called a depthwise filter) or a reduced depth or number of channels (e.g., a 3×3×k filter, where k<depth or number of channels). Each channel, depth or feature map can have an associated filter. Each associated filter can be configured to emphasize different aspects of a channel. In other words, different features can be extracted from each channel based on the filter (this is sometimes called a depthwise separable filter). Other filters are within the scope of this disclosure.

Another type of convolution can be a combination of two or more convolutions. For example, a convolution can be a depthwise and pointwise separable convolution. This can include, for example, a convolution in two steps. The first step can be a depthwise convolution (e.g., a 3×₃ convolution). The second step can be a pointwise convolution (e.g., a 1×1 convolution). The depthwise and pointwise convolution can be a separable convolution in that a different filter (e.g., filters to extract different features) can be used for each channel or ay each depth of a feature map. In an example implementation, the pointwise convolution can transform the feature map to include c channels based on the filter. For example, an 8×8×3 feature map (or image) can be transformed to an 8×8×256 feature map (or image) based on the filter. In some implementation more than one filter can be used to transform the feature map to an M×M×c feature map.

A convolution can be linear. A linear convolution describes the output, in terms of the input, as being linear time-invariant (LTI). Convolutions can also include a rectified linear unit (ReLU). A ReLU is an activation function that rectifies the LTI output of a convolution and limits the rectified output to a maximum. A ReLU can be used to accelerate convergence (e.g., more efficient computation).

Convolution layers can be configured to incrementally transform the feature map to a 1×1×256 feature map. This incremental transformation can cause the generation of bounding boxes (regions of the feature map or grid) of differing sizes which can enable the detection of objects of many sizes. Each cell can have at least one associated bounding box. In an example implementation, the larger the grid (e.g., number of cells) the fewer the number of bounding boxes per cell. For example, the largest grids can use three (3) bounding boxes per cell and the smaller grids can use six (6) bounding boxes per cell. The bounding boxes can be based on locations or possible locations within a physical space (e.g., physical space 400).

Data can be associated with the features in the bounding box. The data can indicate an object in the bounding box (the object can be no object or a portion of an object). An object can be identified by its features. The data, cumulatively, is sometimes called a class or classifier. The class or classifier can be associated with an object. The data (e.g., a bounding box) can also include a confidence score (e.g., a number between zero (0) and one (1)). The at least one feature classification layer 710 can process the data associated with the features in the bounding box

An object (or a portion of an object) as a location can be within a plurality of overlapping bounding boxes. However, the confidence score for each of the classifiers can be different. For example, a classifier that identifies a portion of an object can have a lower confidence score than a classifier that identifies a complete (or substantially complete) object. Bounding boxes without an associated classifier can be discarded. Some ML models can include a suppression layer that can be configured to sort the bounding boxes based on the confidence score and can select the bounding box with the highest score as the classifier identifying a location.

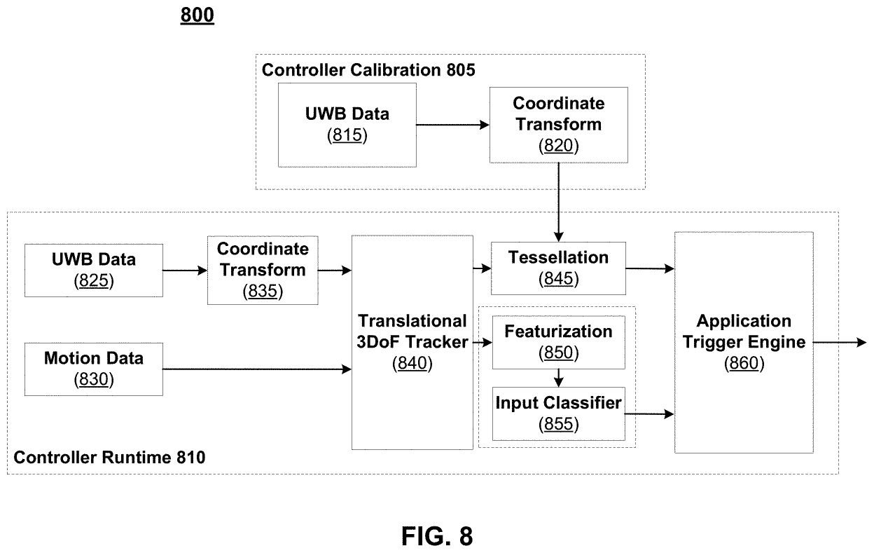

The trigger decision 715 block can be configured to select a smart device(s) and determine an action to be initiated on or by the selected smart device(s). For example, the at least one feature classification layer 710 can output a location (e.g., room 1, position A) and the trigger decision 715 block can determine that the anchor 115 is also the home assistant to initiate an action. The anchor 115 (as the controller smart device) can detect that the user 105 has performed a gesture associated with locking the door and causes a smart lock of the door to be in the locked state. The trigger decision 715 block can be configured to use a database including locations and smart devices stored in relation to (e.g., at the anchor 115) the spatially-aware controller. The trigger decision 715 block can use the database to look-up the smart device(s) based on the location determined by the at least one feature classification layer 710. The database can be configured to store relationships between smart device(s) and locations during a calibration process. The ML model can be an element(s) of a larger system associated with the spatially-aware controller (e.g., anchor 115 and tag 110). FIG. 8 is used to describe a signal flow associated with this larger system.

FIG. 8 illustrates a block diagram of a signal flow for triggering an application according to at least one example embodiment. As shown in FIG. 8, a signal flow 800 includes a controller calibration 805 block and a controller runtime 810 block. The controller can be a spatially-aware controller. Therefore, the controller calibration 805 block and the controller runtime 810 block can be implemented through operation of a memory (e.g., a non-transitory computer readable memory) and a processor associated with an anchor (e.g., anchor 115) and/or a tag (e.g., tag 110). The controller calibration 805 block includes an ultra-wideband (UWB) data 815 block and a coordinate transform 820 block. The controller runtime 810 block includes a UWB data 825 block, a motion data 830 block, a coordinate transform 835 block, a translational 3DoF tracker 840 block, a tessellation 845 block, a featurization 850 block, an input classifier 855 block, and an application trigger engine 860 block.

The UWB data 815, 825 block can be configured to acquire and/or store UWB data. The UWD data can include at least one time, at least one distance and/or at least one angle. The at least one time can be the times associated with total time delay (RTT) (see eqn. 1) acquired during a UWB ranging operation. The at least one distance can be a distance calculated (see eqn. 2) during a UWB ranging operation based on the at least one time. For example, the at least one time can be associated with UWB signal transmission between an anchor (e.g., anchor 115, 205) and a tag (e.g. tag 110, 210). The at least one distance can be a distance (e.g., distance r) between the anchor and the tag that can be calculated using total delay (RTT). The at least one angle can be an angle-of-arrival (AoA) determined during the UWB ranging operation. The AoA of a pulse or UWB signal can be determined by comparing phase shifts over multiple antennas using beamforming techniques (see FIG. 2C).

The coordinate transform 820, 835 block can be configured to generate cartesian coordinates associated with the location of a tag using the UWB data. For example, the at least one distance and the at least one angle can be used to calculate (see eqn. 3) cartesian coordinates (x, y) corresponding to the position of a tag (e.g., tag 110) relative to the position of an anchor (e.g., anchor 115). The coordinate transform 820, 835 block can be configured to generate at least one BUNDLE (see eqn. 3) based on the UWB data. Controller calibration 805 can be implemented during a calibration process using at least one of the calibration techniques (e.g., one-click, N-click, and the like) described above. Controller runtime 810 can be implemented when a smart device action is triggered and/or to trigger a smart device action.

The motion data 830 block can be configured to detect motion (e.g., a gesture) of the controller. Motion detection can correspond to measurements of an accelerometer. In an example implementation, the controller can include an inertial measurement unit (IMU). The IMU can be configured to measure and report velocity, orientation, and gravitational forces, using a combination of sensors (accelerometers, gyroscopes and magnetometers). For example, the IMU can report pitch, yaw, and roll. Therefore, the EAU can be used for three (3) degrees of freedom (3DoE) movement measurements.

The translational 3DoF tracker 840 block can be configured to determine translational (e.g., forward, backward, lateral, or vertical) movement and 3DoF (e.g., left or right turn, up or down tilt, or left and right pivot) movement. Translational 3DoF is sometimes called six (6) degrees of freedom (6DoF). Accordingly, the translational 3DoF tracker 840 enables a spatially-aware controller to track whether the a spatially-aware controller has moved forward, backward, laterally, or vertically for gesture determination. A spatially-aware controller may not include the translational 3DoF tracker 840 (e.g., not include an IMU). In this case, the spatially-aware controller is not configured for gesture detection.

The tessellation 845 block can be configured to applying a Euclidean distance metric to Voronoi-tessellate the space can be used when determining proximity to a location (e.g., coordinate) of interest (e.g., the calibrated locations). Tessellation 845 can create a mesh that can represent a physical space (e.g., physical space 400) and the zones (e.g., rooms and objects) of the physical space. Tessellation can be a three-dimensional (3D) representation of the physical space 400 in a two-dimensional (2D) coordinate system. Therefore, tessellation can also include mapping coordinates from one 2D representation (range and angle) to another 2D representation (mesh).

The featurization 850 block can be configured to implement the at least one convolution/pooling layer 705. The input classifier 855 block can be configured to implement the at least one feature classification layer 710. Therefore, featurization 850 and input classifier 855 can include implementation of a ML model (illustrated as the dashed line around the featurization 850 block and the input classifier 855 block). The input classifier 855 can generate an output including location or location and gesture. If there is an IMU, the at least one convolution/pooling layer 705 can have five layers (e.g., x, y associated with the location and x, y, z associated with the gesture). If there is not an IMU, the at least one convolution/pooling layer 705 can have two layers (e.g., x, y associated with the location). If there is an IMU and the controller is not determining location (e.g., location has previously been resolved), the at least one convolution/pooling layer 705 can have three layers (e.g., x, y, z associated with the gesture).

The application trigger engine 860 block. can be configured to select a smart device(s) and determine an action to be initiated on or by the selected smart device(s). For example, the input classifier 855 can output a location (e.g., room 1, position A) and/or a gesture interpretation. The anchor (as the controller smart device) or a smart device can cause an action (e.g., light on, lock door, change channel, and/or the like) to be performed based on the location and/or the gesture. The application trigger engine 860 block can be configured to use a database including locations and smart devices stored in relation to (e.g., at the anchor 115) the spatially-aware controller. The application trigger engine 860 block can use the database to look-up the smart device(s) based on the location determined by the input classifier 855.

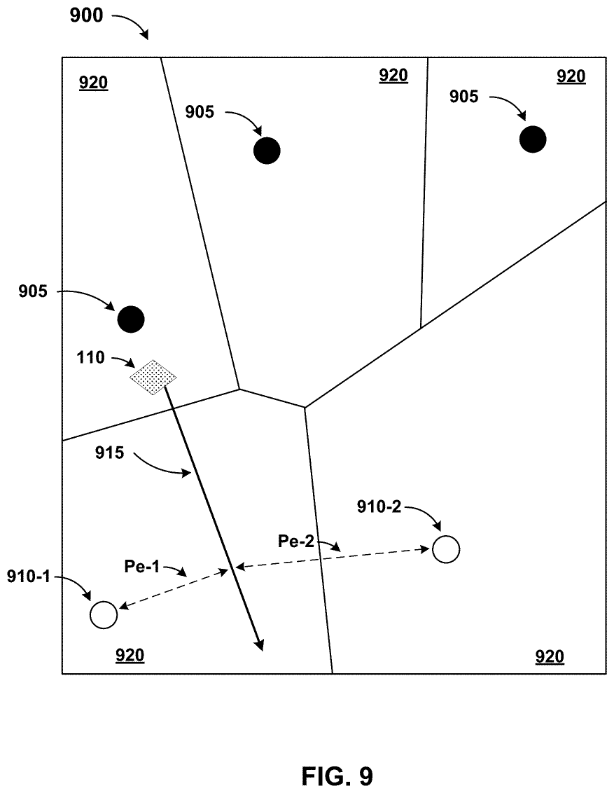

Example implementations may include determining which (if any) object (e.g., smart device, controllable device, and/or the like) the spatially-aware controller is pointing toward. Determining which object the spatially-aware controller is pointing toward can indicate an intent of the user (e.g., which device toes the user want to control). Determining which object the spatially-aware controller is pointing toward can be described using FIG. 9. FIG. 9 illustrates a pictorial representation of a tiled view of coordinates and a pointing ray within a portion of a physical space according to at least one example embodiment. As shown in FIG. 9, a tiled (e.g., tessellation) view 900 can include a plurality of tiles 920.

Tiles 920 each include one coordinate associated with a physical space or a portion of a physical space (e.g., physical space 400). The coordinates can be based on UWB range and angle data (e.g., captured during a calibration process described above). The UWB range and angle data can be stored (e.g., in a database) in association with the anchor 115 and/or the tag 110. During use (e.g., a runtime operation) of the spatially-aware controller, the UWB range and angle data can be can be retrieved (e.g., read from the database), formatted in a 2D (e.g., cartesian) coordinate system, and used to generate the tiled view 900.

For example, generating a tiled (e.g., tessellation) view of coordinates can include applying a Euclidean distance metric to Voronoi-tessellate the space The tessellated space can be used when determining proximity to a location (e.g., coordinate) of interest (e.g., the calibrated locations). Tessellation can create tiles, a mesh, a set of connected geometric shapes, and the like that can represent the physical space and the zones (e.g., rooms and objects) of the physical space. Tessellation can cause the two-dimensional (2D) space to appear as a three-dimensional (3D) representation of the physical space.

In FIG. 9, a closed circle (or filled in circle) can represent a location without an object. Therefore, coordinates 905 represent locations without an object. An open circle can represent a location with an object. Therefore, coordinates 910-1, 910-2 represent locations with an object. A pointing ray 915 can represent a signal path based on a direction the spatially-aware controller is pointed. As shown in FIG. 9, the pointing ray 915 indicates that the spatially-aware controller is not pointed directly at an object (e.g., a device to be controlled). Therefore, the spatially-aware controller can trigger an operation to determine the users intent.

Determining the users intent can include determining (e.g., calculating, computing, and the like) a projection error associated with each of coordinates 910-1, 910-2. The projection error can indicate how close the pointing ray 915 is to a coordinate. The closer the coordinate is to the pointing ray, the lower the projection error should be. The smallest projection error of a set of determined projection errors should identify the user intends to control (e.g., indicate the users intent). The projection error associated with coordinate 910-1 is illustrated as dashed line Pe-1. The projection error associated with coordinate 910-2 is illustrated as dashed line Pe-2. Projection error can be calculated as:

$$\begin{matrix}Pe = {arg min}_{k = \{ 0 , 1 , 2 , … , n - 1} {ℒ}_{proj} ( x , \hat{x} , \hat{v} ) \\ = {arg min}_{k = \{ 0 , 1 , 2 , … , n - 1} {‖ {x}_{k} - {proj}_{( \hat{x} , \hat{v} )} ( {x}_{k} ) ‖}_{2}^{2}\end{matrix} \qquad ( 13 )$$

This calculation of projection error does not explicitly include the condition that the pointing ray 915 is one-directional and has a starting point (=location of the controller) at non-infinity. Therefore, a barrier regularization term (e.g., a sigmoid function with a boundary in the orthogonal direction of pointing vector) in the cost minimizes the effect as:

[symbol]

ₚᵣₒⱼ(x,\hat{x},\hat{v})+λ· [symbol] _{barrier}(x,\hat{x},\hat{v}) (14)

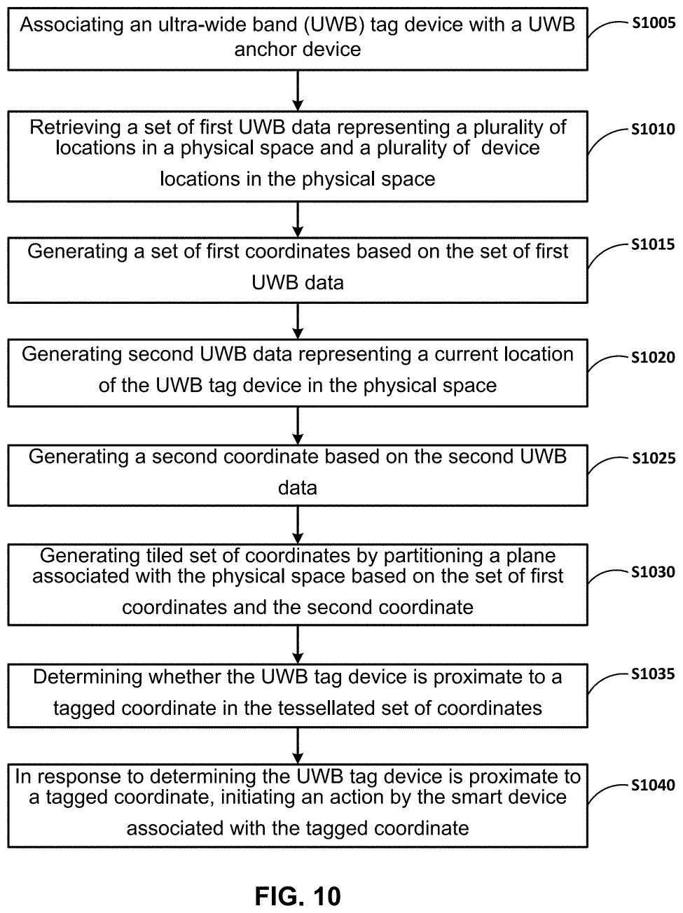

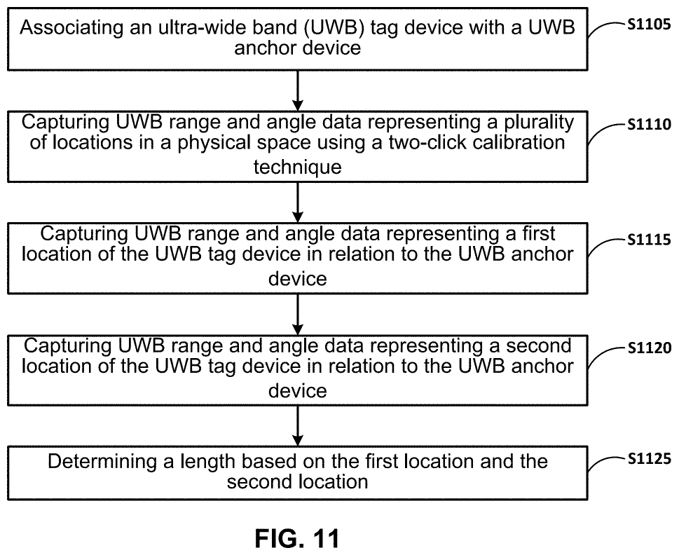

FIGS. 10 and 11 are flowcharts of methods according to example embodiments. The methods described with regard to FIGS. 10 and 11 may be performed due to the execution of software code stored in a memory (e.g., a non-transitory computer readable storage medium) associated with an apparatus and executed by at least one processor associated with the apparatus.

However, alternative embodiments are contemplated such as a system embodied as a special purpose processor. The special purpose processor can be an application specific integrated circuit (ASIC), a graphics processing unit (GPU) and/or an audio processing unit (APU). A GPU can be a component of a graphics card. An APU can be a component of a sound card. The graphics card and/or sound card can also include video/audio memory, random access memory digital-to-analogue converter (RAMDAC) and driver software. The driver software can be the software code stored in the memory referred to above. The software code can be configured to implement the method described herein.

Although the methods described below are described as being executed by a processor and/or a special purpose processor, the methods are not necessarily executed by a same processor. In other words, at least one processor and/or at least one special purpose processor may execute the method described below with regard to FIGS. 10 and 11.

FIG. 10 is a flowchart of a method for initiating a smart device action based on location according to at least one example embodiment. As shown in FIG. 10, in step S1005 an ultra-wide band (UWB) tag device is associated with a UWB anchor device. Associating the UWB tag device with the UWB anchor device can form, generate, or be referred to as a spatially-aware controller. For example, tag 110 can be associated with anchor 115. Associating the UWB tag device with the UWB anchor device can include at least on of performing a calibration operation and/or performing a non-linear correction of at least one distance between the UWB tag device and the UWB anchor device. Information corresponding to associating the UWB tag device with the UWB anchor device can be stored (e.g., in a database) in relation to, for example, the anchor (e.g., anchor 115).

In step S1010 a set of first UWB data representing a plurality of locations in a physical space and a plurality of device locations in the physical space is retrieved. For example, a database can include UWB data collected during a calibration process. The UWB data can include range and angle data associated with locations that can, for example, represent a zone (e.g., a portion of the physical space (e.g., a room)) or a location within a zone (e.g., a location of interest (e.g., proximate to a door) within a room. The device can be a location associated with one or more smart devices. The device location can be a location associated with one or more devices to control (e.g., a television). The device location can be a location associated with some other type of object (e.g., furniture). In an example implementation the first UWB data representing the plurality device locations can be tagged as associated with a device. For example, entries within the database can include the device UWB data indicating a location, an entry identifying the UWB data as associated with a device (e.g., tagged), information (e.g., type, functionality, and the like), and/or the like.

In step S1015 a set of first coordinates is generated based on the set of first UWB data. For example, UWB range and angle data associated with the set of first coordinates can be formatted into a coordinate (e.g., cartesian) system. The UWB range and angle data can be formatted based on the development of eqn. 3.

In step S1020 second UWB data representing a current location of the UWB tag device in the physical space is generated. For example, the UWB data can include range and angle data associated with a current location of a user (e.g., user 105) in possession of the UWB tag device (e.g., tag 110). The UWB data can be acquired through signal communication between the anchor device and the tag device. The range can be based on a transmission time delay (e.g., RTT). The angle can be based on a signal received at the anchor device from the tag device. The angle can be an angle-of-arrival (AoA).

In step S1025 a second coordinate is generated based on the second UWB data. For example, UWB range and angle data associated with the set of first coordinates can be formatted into a coordinate (e.g., cartesian) system. The UWB range and angle data can be formatted based on the development of eqn. 3.

In step S1030 a tiled set of coordinates is generated by partitioning a plane associated with the physical space based on the set of first coordinates and the second coordinate. For example, generating a tiled (e.g., tessellation) set of coordinates or tiled view of coordinates can include applying a Euclidean distance metric to Voronoi-tessellate the space The tessellated space can be used when determining proximity to a location (e.g., coordinate) of interest (e.g., the calibrated locations). Tessellation can create tiles, a mesh, a set of connected geometric shapes, and the like that can represent the physical space and the zones (e.g., rooms and objects) of the physical space.

In step S1035 whether the UWB tag device is proximate to a tagged coordinate in the tiled set of coordinates is determined. For example, one of the coordinates can identify, for example, a tagged device. The proximity of a tile including the second coordinate (associated with the user) to a tile including the coordinate that identifies the tagged device can indicate whether the UWB tag device is proximate to a tagged coordinate. For example, if the tile including the coordinate representing the UWB tag device is within a threshold number of tiles of the tile including the coordinate that identifies the tagged device, the UWB tag device can be determined as proximate to a tagged coordinate. For example, if the tile including the coordinate representing the UWB tag device is same zone (or room) of the tile including the coordinate that identifies the tagged device, the UWB tag device can be determined as proximate to a tagged coordinate.

In addition to determining whether the UWB tag device is proximate to a tagged coordinate in the tiled set of coordinates, a pointing ray representing a direction the user is pointing the UWB tag device can be determined. For example, the direction of the pointing ray can be associated with an angle-of-arrival (AoA) of the UWB tag device. The AOA of a pulse of the UWB tag device can be determined by comparing phase shifts over multiple antennas of the UWB tag device using beamforming techniques. Assuming the antennas of the UWB tag device are pointing in the direction the user is pointing the UWB tag device (e.g., the antennas are not pointing toward the user), the AOA associated with the UWB tag device can direction the user is pointing the UWB tag device.

In step S1040 in response to determining the UWB tag device is proximate to a tagged coordinate, an action by the device associated with the tagged coordinate is initiated. For example, a ML model can determine an action to perform. The database can include the action to perform. The state (e.g., door unlocked/locked, light on/off, device on/off) can indicate the action to be performed. The action can be to disable a device (e.g., a home assistant) so that only one device performs an action. The action can be based on a voice command, a user gesture, and/or the like.

In an example implementation, a calibration operation that includes capturing UWB range and angle data based on a location of the UWB tag device relative to the UWB anchor device can be performed prior to retrieving a set of first UWB data. The calibration operation can include capturing UWB range and angle data representing the plurality of locations in the physical space using a one-click-per-zone calibration technique, capturing UWB range and angle data representing the plurality device locations using a N-click calibration technique, and associating a tag with UWB range and angle data representing each of the plurality device locations. Capturing UWB range and angle data can include transmitting a first signal from the UWB anchor device to the UWB tag device, determining a delay time associated with a second signal received, in response to the first signal, by the UWB anchor device from the UWB tag device, determining a distance based on the delay time, and determining an angle-of-arrival (AoA) based on the second signal.

In an example implementation, ranges associated with the UWB data can be non-linear corrected using a trained polynomial regression model. The determining of whether the UWB tag device is proximate to a tagged coordinate is triggered by at least one of a user voice command and a user gesture. For example, a user can call a voice command. The user can be within range of two devices (e.g., a home assistant) that can respond (e.g., play music) to the voice command. The action can be triggered to prevent more than one device responding to the voice command. In other words, a first device and a second device can be configured to perform a same action, and whether the first device or the second device initiates performance of the same action can be based on the location of the UWB tag device. The triggering of the determination of which of the first device or the second device should perform the action can be the voice command.

In an example implementation, the UWB tag device includes a component configured to measure six (6) degrees of freedom (6DoF) data, and the initiating of the action by the at least one device includes determining the action to initiate using a trained ML model having the second coordinate and the 6DoF data as input. Prior to initiating the action by the device, a user intent can be determined based on a projection error associated with a pointing ray representing a direction the user is pointing the device. The UWB tag device can be a mobile computing device (e.g., as shown in FIG. 1) and the UWB anchor device can be a stationary computing device (e.g., as shown in FIG. 1).

FIG. 11 is a flowchart of a method for measuring a length according to at least one example embodiment. As shown in FIG. 11, in step S1105 an ultra-wide band (UWB) tag device is associated with a UWB anchor device. Associating the UWB tag device with the UWB anchor device can form, generate, or be referred to as a spatially-aware controller that can be used as an electronic or digital measuring device. For example, tag 110 can be associated with anchor 115. Associating the UWB tag with the UWB anchor device can include at least on of performing a calibration operation and/or performing a non-linear correction of at least one distance between the UWB tag device and the UWB anchor device. Information corresponding to associating the UWB tag device with the UWB anchor device can be stored (e.g., in a database) in relation to, for example, the anchor device (e.g., anchor 115).

In step S1110 UWB range and angle data representing a plurality of locations in a physical space is captured using a calibration technique. For example, the calibration technique can be the one-click calibration technique. The one-click calibration technique (as discussed above can include (for the tag device in one location) transmitting a first signal from the UWB anchor device to the UWB tag device, determining a delay time associated with a second signal received, in response to the first signal, by the UWB anchor device from the UWB tag device, determining a distance based on the delay time, and determining an angle-of-arrival (AoA) based on the first signal and the second signal. The range and angle data can be stored in, for example, a database associated with the anchor device. The range associated with the UWB data can be non-linear corrected using a trained polynomial regression model.

In step S1115 UWB range and angle data representing a first location of the UWB tag device in relation to the UWB anchor device is captured. Similar to the one-click calibration, capturing UWB range and angle data representing a first location can include transmitting a first signal from the UWB anchor device to the UWB tag device, determining a delay time associated with a second signal received, in response to the first signal, by the UWB anchor device from the UWB tag device, determining a distance based on the delay time, and determining an AoA based on the first signal and the second signal. The first location can be a first side of an object or distance to determine a length. The range associated with the UWB data can be non-linear corrected using a trained polynomial regression model.

In step S1120 UWB range and angle data representing a second location of the UWB tag device in relation to the UWB anchor device is captured. For example, similar to capturing UWB range and angle data representing the first location, capturing UWB range and angle data representing a second location can include transmitting a first signal from the UWB anchor device to the UWB tag device, determining a delay time associated with a second signal received, in response to the first signal, by the UWB anchor device from the UWB tag device, determining a distance based on the delay time, and determining an AoA based on the first signal and the second signal. The second location can be a second side of an object or distance to determine a length. The range associated with the UWB data can be non-linear corrected using a trained polynomial regression model.

In step S1120 a length is determined based on the first location and the second location. For example, as discussed above, the length can be a distance d that can be determined as the Euclidean norm of the difference in the cartesian coordinates of the first location and the second location. Alternatively, the length can be a circumference of a circle that can be determined using a Riemann sum over a set of measurement data (e.g., a plurality of coordinates determined based on a plurality of locations of the UWB tag device). Other lengths and/or dimensions can be measured based on UWB tag device locations and are within the scope of this disclosure.

Example implementations can include including a spatially-aware controller, a UWB tag device, or a UWB anchor device as an element of augmented reality (AR) glasses. Doing so can enable the AR glasses to perform any of the implementations described above. In addition, other implementations can be based on length measurements as described above. In other words, the UWB tag device can be an element of the AR glasses enabling the AR glasses to perform and use electronic or digital measurements. In some implementations, the calibration technique can be a first calibration technique (e.g., a one-click calibration technique). Implementations can further include capturing UWB range and angle data representing a plurality of object locations using a second calibration technique (e.g., a N-click calibration technique).

The spatially-aware controller can enable the AR glasses to include one or more safety features. For example, the AR glasses can warn a user (e.g., with an audible sound) should the user get to close to an object (e.g., a burn hazard, a fall hazard, prevent damage to an object, and/or the like. Accordingly, implementations can include associating the UWB range and angle data representing one of the plurality of object locations with the UWB range and angle data representing a first location, associating UWB range and angle data corresponding to a location of the AR glasses with the UWB range and angle data representing a second location, and warning a user of the AR glasses when the determined length is less than a threshold length value.

The spatially-aware controller can enable the AR glasses to include features that can be enabled should the AR glasses determine the user is proximate to an object. For example, a camera of the AR glasses can be focused, a camera lens can be zoomed to zoom in and display the object on a display of the AR glasses. The AR camera can aid in locating an object.

For example, implementations can include associating the UWB range and angle data representing one of the plurality of object locations with the UWB range and angle data representing a first location, associating UWB range and angle data corresponding to a location of the AR glasses with the UWB range and angle data representing a second location; and focusing a camera of the AR glasses based on the determined length. For example, implementations can include determining the user of the AR glasses is focused on an object of the plurality of objects, associating the UWB range and angle data representing the object location with the UWB range and angle data representing a first location, associating UWB range and angle data corresponding to a location of the AR glasses with the UWB range and angle data representing a second location, and zooming a lens of a camera of the AR glasses based on the determined length for displaying the object on a display of the AR glasses.

For example, implementations can include determining the user of the AR glasses is looking for an object of the plurality of objects, associating the UWB range and angle data representing the object location with the UWB range and angle data representing a first location, associating UWB range and angle data corresponding to a location of the remaining objects of the plurality of objects with the UWB range and angle data representing a second location, and blur or focus a display of the AR glasses based on the determined length. The spatially-aware controller can enable the AR glasses to include virtual reality (VR) as features augmenting features that can be enabled should the AR glasses determine the user is to interact with the VR feature.

For example, implementations can include associating UWB range and angle data a virtual reality (VR) object, associating the UWB range and angle data representing the VR object location with the UWB range and angle data representing a first location, associating UWB range and angle data corresponding to a location of the AR glasses with the UWB range and angle data representing a second location, determining whether the user of the AR glasses is within a range of the VR object based on the determined length, and in response to determining whether the user of the AR glasses is within the range of the VR object, initiating a VR action by the VR object. Implementations can include associating UWB range and angle data a virtual reality (VR) object, associating the UWB range and angle data representing the VR object location with the UWB range and angle data representing a first location, associating UWB range and angle data corresponding to a location of the objects of the plurality of objects with the UWB range and angle data representing a second location, determining the user of the VR glasses is looking at the VR object (e.g., based on a pointing ray as discussed above) and in response to determining the user of the VR glasses is looking at the VR object, adjust an opaqueness of the VR object based on the plurality of objects along a line of sight and the determined length.

The spatially-aware controller can enable features that may or may not be implemented in the AR glasses. For example, the spatially-aware controller can function to aid media casting and device state manipulation. For example, implementations can include determining a user in possession of the spatially-aware controller (e.g., the UWB tag device) has initiated a media casting operation, associating the UWB range and angle data representing each of the plurality of object locations with the UWB range and angle data representing a first location, associating UWB range and angle data corresponding to a location of the AR glasses with the UWB range and angle data representing a second location, determining whether a device capable of receiving and displaying the media casting is within a range of the user based on the determined length, and in response to determining a device capable of receiving and displaying the media casting is within the range of the user, cast the media to the device. Implementations can include determining the user is no longer in range of the device capable of receiving and displaying the media based on the length, determining the user is in range of a second device capable of receiving and displaying the media based on the determined length, and in response to determining second device capable of receiving and displaying the media casting is within the range of the user, end the casting of the media to the device and cast the media to the second device.

For example, implementations can include associating the UWB range and angle data representing one of the plurality of light locations with the UWB range and angle data representing a first location, associating UWB range and angle data corresponding to a location of a user in possession of the UWB tag device with the UWB range and angle data representing a second location, determining whether the user is within a range of a light based on the determined length, in response to determining whether the user is within the range of a light, cause the light to turn on, and in response to determining whether the user is not within the range of a light, cause the light to turn off.

There can be many additional applications for the a spatially-aware controller. For example, a universal home controller, a measurement device, augmented reality (AR) navigation (e.g., a smart ring as a tag and smart glasses as an anchor), home floor plan reconstruction by unsupervised learning, activities of daily life (ADL) tracking for elderly care, movement health applications such as early screening of Parkinson s disease, improving GPS accuracy indoors are just a few examples. For example, an AR navigation use case can include a spatially-aware controller as baseline for low-power translational 3dof (assuming multi-antenna glasses) tracker that can be suitable for AR applications, which should operate in extreme power savings mode for full-day operation. Assuming the smart ring has an IMU, the UWB+IMU fusion tracking model can be utilized. There can be an opportunity of mixing the spatially-aware controller technology with glasses. The smart glasses can act as the remote UWB tag and enabling the spatially-aware controller with eye tracking to establish user intent (e.g., as a gesture) can create an experience where a smart device can be triggered with the user's visual cue and input (e.g. click from wristband).

Implementations can include a device, a system, a non-transitory computer-readable medium (having stored thereon computer executable program code which can be executed on a computer system), and/or a method can perform a process with a method including associating an ultra-wide band (UWB) tag device with a UWB anchor device, retrieving a set of first UWB data representing a plurality of locations in a physical space and a plurality of device locations in the physical space, the first UWB data representing the plurality device locations being tagged as associated with a device, generating a set of first coordinates based on the set of first UWB data, generating second UWB data representing a current location of the UWB tag device in the physical space, generating a second coordinate based on the second UWB data, generating a tiled set of coordinates by partitioning a plane associated with the physical space based on the set of first coordinates and the second coordinate, determining whether the UWB tag device is proximate to a tagged coordinate in the tiled set of coordinates, and in response to determining the UWB tag device is proximate to a tagged coordinate, initiating an action by the device associated with the tagged coordinate.

Implementations can include one or more of the following features. For example, prior to retrieving a set of first UWB data, performing a calibration operation that can include capturing UWB range and angle data based on a location of the UWB tag device relative to the UWB anchor device. Prior to retrieving a set of first UWB data, performing a calibration operation that can include capturing UWB range and angle data representing the plurality of locations in the physical space using a first calibration technique, capturing UWB range and angle data representing the plurality device locations using a second calibration technique, and associating a tag with UWB range and angle data representing each of the plurality device locations. The capturing UWB range and angle data can includes transmitting a first signal from the UWB anchor device to the UWB tag device, determining a delay time associated with a second signal received, in response to the first signal, by the UWB anchor device from the UWB tag device, determining a distance based on the delay time, and determining an angle-of-arrival (AoA) based on the second signal.

For example, the generating of the set of first coordinates based on the set of first UWB data can include formatting range and angle data into a two-dimensional (2D) coordinate system. At least one range associated with the UWB data can be non-linear corrected using a trained polynomial regression model. The generating of the tiled set of coordinates can include applying a Euclidean distance metric to Voronoi-tessellate the plane associated with the physical space. The determining of whether the UWB tag device is proximate to a tagged coordinate can be triggered by at least one of a user voice command and a user gesture. A first device and a second device can be configured to perform a same action, and whether the first device or the second device initiates performance of the same action is based on the location of the UWB tag device. The initiating of the action by the device can include determining the action to initiate using a trained ML model. The UWB tag device can include a component configured to measure six (6) degrees of freedom (6DoE) data, and the initiating of the action by the device can include determining the action to initiate using a trained ML model having the second coordinate and the 6DoF data as input. Prior to initiating the action by the device, determining a direction a user is pointing the UWB tag device can be based on an AoA associated with the UWB tag device. Prior to initiating the action by the device, determining a user intent can be based on a projection error associated with a pointing ray representing a direction the user is pointing the device. The UWB tag device can be a mobile computing device and the UWB anchor device can be a stationary computing device.

Implementations can include a device, a system, a non-transitory computer-readable medium (having stored thereon computer executable program code which can be executed on a computer system), and/or a method can perform a process with a method including associating an ultra-wide band (UWB) tag device with a UWB anchor device, capturing UWB range and angle data representing a plurality of locations in a physical space using a calibration technique, capturing UWB range and angle data representing a first location of the UWB tag device in relation to the UWB anchor device, capturing UWB range and angle data representing a second location of the UWB tag device in relation to the UWB anchor device, and determining a length based on the first location and the second location.

Implementations can include one or more of the following features. For example, at least one range associated with the UWB data can be non-linear corrected using a trained polynomial regression model. The length can be determined as the Euclidean norm of the difference in the cartesian coordinates of the first location and the second location. The length can be a circumference of a circle that can be determined using a Riemann sum over a set of locations including the first location and the second location. The capturing of UWB range and angle data can include transmitting a first signal from the UWB anchor device to the UWB tag device, determining a delay time associated with a second signal received, in response to the first signal, by the UWB anchor device from the UWB tag device, determining a distance based on the delay time, determining an angle-of-arrival (AoA) based on the first signal and the second signal, and determining two-dimensional (2D) coordinates corresponding to the location of the UWB tag device.

For example, the calibration technique can be a first calibration technique and the UWB tag device can be an element of augmented reality (AR) glasses, the method can further include capturing UWB range and angle data representing a plurality of object locations using a second calibration technique associating the UWB range and angle data representing one of the plurality of object locations with the UWB range and angle data representing a first location, associating UWB range and angle data corresponding to a location of the AR glasses with the UWB range and angle data representing a second location, and warning a user of the AR glasses when the determined length is less than a threshold length value. The calibration technique can be a first calibration technique and the UWB tag device can be an element of AR glasses, the method can further include capturing UWB range and angle data representing a plurality of object locations using a second calibration technique, associating the UWB range and angle data representing one of the plurality of object locations with the UWB range and angle data representing a first location, associating UWB range and angle data corresponding to a location of the AR glasses with the UWB range and angle data representing a second location, and focusing a camera of the AR glasses based on the determined length.

For example, the calibration technique can be a first calibration technique and the UWB tag device can be an element of AR glasses, the method can further include capturing UWB range and angle data representing a plurality of object locations using a second calibration technique, determining the user of the AR glasses is focused on an object of the plurality of objects, and in response to determining the user of the AR glasses is focused on an object of the plurality of objects associating the UWB range and angle data representing the object location with the UWB range and angle data representing a first location, associating UWB range and angle data corresponding to a location of the AR glasses with the UWB range and angle data representing a second location, and zooming a lens of a camera of the AR glasses based on the determined length for displaying the object on a display of the AR glasses. The calibration technique can be a first calibration technique and the UWB tag device can be an element of AR glasses, the method can further include capturing UWB range and angle data representing a plurality of object locations using a second calibration technique, determining the user of the AR glasses is looking for an object of the plurality of objects, and in response to determining the user of the AR glasses is looking for an object of the plurality of objects associating the UWB range and angle data representing the object location with the UWB range and angle data representing a first location, associating UWB range and angle data corresponding to a location of the remaining objects of the plurality of objects with the UWB range and angle data representing a second location, and blurring or focusing a display of the AR glasses based on the determined length.

For example, the calibration technique can be a first calibration technique and the UWB tag device can be an element of AR glasses, the method can further include capturing UWB range and angle data representing a plurality of object locations using a second calibration technique, associating UWB range and angle data a virtual reality (VR) object, associating the UWB range and angle data representing the VR object location with the UWB range and angle data representing a first location, associating UWB range and angle data corresponding to a location of the AR glasses with the UWB range and angle data representing a second location, determining whether the user of the AR glasses is within a range of the VR object based on the determined length, and in response to determining whether the user of the AR glasses is within the range of the VR object, initiating a VR action by the VR object. The calibration technique can be a first calibration technique and the UWB tag device is an element of AR glasses, the method can further include capturing UWB range and angle data representing a plurality of object locations using a second calibration technique, associating UWB range and angle data a virtual reality (VR) object, associating the UWB range and angle data representing the VR object location with the UWB range and angle data representing a first location, associating UWB range and angle data corresponding to a location of the objects of the plurality of objects with the UWB range and angle data representing a second location, determining the user of the VR glasses is looking at the VR object, and in response to determining the user of the VR glasses is looking at the VR object, adjusting an opaqueness of the VR object based on the plurality of objects along a line of sight and the determined length.

For example, the calibration technique can be a first calibration technique, the method can further include capturing UWB range and angle data representing a plurality of object locations using a second calibration technique, determining a user in possession of the UWB tag device has initiated a media casting operation, and in response to determining the user has initiated a media casting operation associating the UWB range and angle data representing each of the plurality of object locations with the UWB range and angle data representing a first location, associating UWB range and angle data corresponding to a location of the AR glasses with the UWB range and angle data representing a second location, determining whether a device capable of receiving and displaying the media casting is within a range of the user based on the determined length, and in response to determining a device capable of receiving and displaying the media casting is within the range of the user, casting the media to the device. The method can further include determining the user is no longer in range of the device capable of receiving and displaying the media based on the length, determining the user is in range of a second device capable of receiving and displaying the media based on the determined length, and in response to determining second device capable of receiving and displaying the media casting is within the range of the user, ending the casting of the media to the device and casting the media to the second device.

For example, the calibration technique can be a first calibration technique, the method can further include capturing UWB range and angle data representing a plurality of light locations using a second calibration technique, associating the UWB range and angle data representing one of the plurality of light locations with the UWB range and angle data representing a first location, associating UWB range and angle data corresponding to a location of a user in possession of the UWB tag device with the UWB range and angle data representing a second location, determining whether the user is within a range of a light based on the determined length, in response to determining whether the user is within the range of a light, causing the light to turn on, and in response to determining whether the user is not within the range of a light, causing the light to turn off.

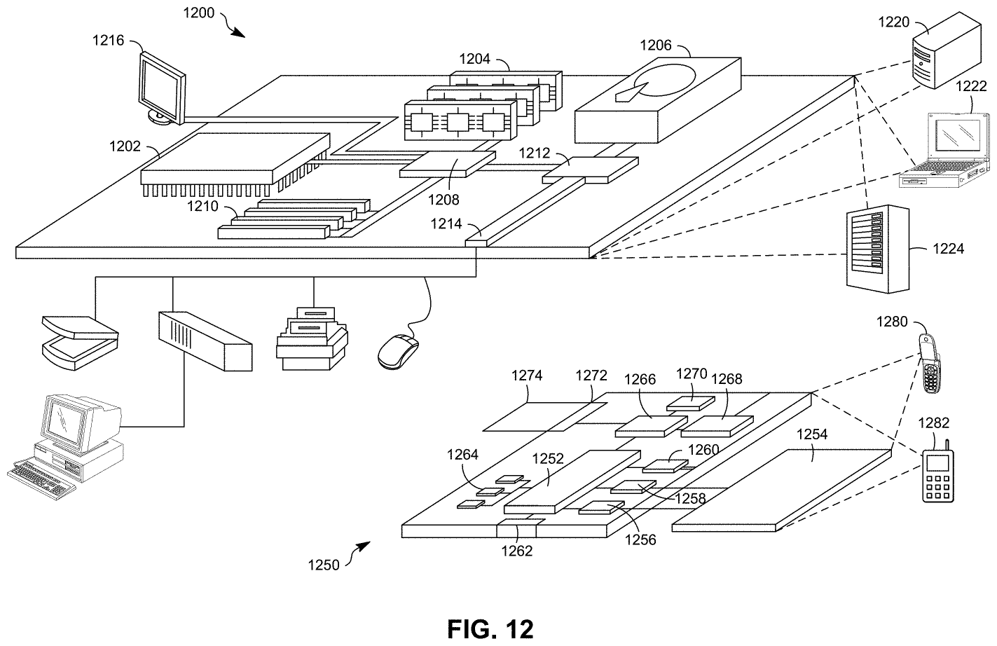

FIG. 12 shows an example of a computer device 1200 and a mobile computer device 1250, which may be used with the techniques described here. Computing device 1200 is intended to represent various forms of digital computers, such as laptops, desktops, workstations, personal digital assistants, servers, blade servers, mainframes, and other appropriate computers. Computing device 1250 is intended to represent various forms of mobile devices, such as personal digital assistants, cellular telephones, smart phones, and other similar computing devices. The components shown here, their connections and relationships, and their functions, are meant to be exemplary only, and are not meant to limit implementations of the inventions described and/or claimed in this document.

Computing device 1200 includes a processor 1202, memory 1204, a storage device 1206, a high-speed interface 1208 connecting to memory 1204 and high-speed expansion ports 1210, and a low speed interface 1212 connecting to low speed bus 1214 and storage device 1206. Each of the components 1202, 1204, 1206, 1208, 1210, and 1212, are interconnected using various busses, and may be mounted on a common motherboard or in other manners as appropriate. The processor 1202 can process instructions for execution within the computing device 1200, including instructions stored in the memory 1204 or on the storage device 1206 to display graphical information for a GUI on an external input/output device, such as display 1216 coupled to high speed interface 1208. In other implementations, multiple processors and/or multiple buses may be used, as appropriate, along with multiple memories and types of memory. Also, multiple computing devices 1200 may be connected, with each device providing portions of the necessary operations (e.g., as a server bank, a group of blade servers, or a multi-processor system).

The memory 1204 stores information within the computing device 1200. In one implementation, the memory 1204 is a volatile memory unit or units. In another implementation, the memory 1204 is a non-volatile memory unit or units. The memory 1204 may also be another form of computer-readable medium, such as a magnetic or optical disk.

The storage device 1206 is capable of providing mass storage for the computing device 1200. In one implementation, the storage device 1206 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier is a computer- or machine-readable medium, such as the memory 1204, the storage device 1206, or memory on processor 1202.

The high speed controller 1208 manages bandwidth-intensive operations for the computing device 1200, while the low speed controller 1212 manages lower bandwidth-intensive operations. Such allocation of functions is exemplary only. In one implementation, the high-speed controller 1208 is coupled to memory 1204, display 1216 (e.g., through a graphics processor or accelerator), and to high-speed expansion ports 1210, which may accept various expansion cards (not shown). In the implementation, low-speed controller 1212 is coupled to storage device 1206 and low-speed expansion port 1214. The low-speed expansion port, which may include various communication ports (e.g., USB, Bluetooth, Ethernet, wireless Ethernet) may be coupled to one or more input/output devices, such as a keyboard, a pointing device, a scanner, or a networking device such as a switch or router, e.g., through a network adapter.

The computing device 1200 may be implemented in a number of different forms, as shown in the figure. For example, it may be implemented as a standard server 1220, or multiple times in a group of such servers. It may also be implemented as part of a rack server system 1224. In addition, it may be implemented in a personal computer such as a laptop computer 1222. Alternatively, components from computing device 1200 may be combined with other components in a mobile device (not shown), such as device 1250. Each of such devices may contain one or more of computing device 1200, 1250, and an entire system may be made up of multiple computing devices 1200, 1250 communicating with each other.

Computing device 1250 includes a processor 1252, memory 1264, an input/output device such as a display 1254, a communication interface 1266, and a transceiver 1268, among other components. The device 1250 may also be provided with a storage device, such as a microdrive or other device, to provide additional storage. Each of the components 1250, 1252, 1264, 1254, 1266, and 1268, are interconnected using various buses, and several of the components may be mounted on a common motherboard or in other manners as appropriate.

The processor 1252 can execute instructions within the computing device 1250, including instructions stored in the memory 1264. The processor may be implemented as a chipset of chips that include separate and multiple analog and digital processors. The processor may provide, for example, for coordination of the other components of the device 1250, such as control of user interfaces, applications run by device 1250, and wireless communication by device 1250.

Processor 1252 may communicate with a user through control interface 1258 and display interface 1256 coupled to a display 1254. The display 1254 may be, for example, a TFT LCD (Thin-Film-Transistor Liquid Crystal Display) or an OLED (Organic Light Emitting Diode) display, or other appropriate display technology. The display interface 1256 may comprise appropriate circuitry for driving the display 1254 to present graphical and other information to a user. The control interface 1258 may receive commands from a user and convert them for submission to the processor 1252. In addition, an external interface 1262 may be provide in communication with processor 1252, to enable near area communication of device 1250 with other devices. External interface 1262 may provide, for example, for wired communication in some implementations, or for wireless communication in other implementations, and multiple interfaces may also be used.

The memory 1264 stores information within the computing device 1250. The memory 1264 can be implemented as one or more of a computer-readable medium or media, a volatile memory unit or units, or a non-volatile memory unit or units. Expansion memory 1274 may also be provided and connected to device 1250 through expansion interface 1272, which may include, for example, a SIMM (Single In Line Memory Module) card interface. Such expansion memory 1274 may provide extra storage space for device 1250, or may also store applications or other information for device 1250. Specifically, expansion memory 1274 may include instructions to carry out or supplement the processes described above, and may include secure information also. Thus, for example, expansion memory 1274 may be provide as a security module for device 1250, and may be programmed with instructions that permit secure use of device 1250. In addition, secure applications may be provided via the SIMM cards, along with additional information, such as placing identifying information on the SIMM card in a non-hackable manner.

The memory may include, for example, flash memory and/or NV RAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 1264, expansion memory 1274, or memory on processor 1252, that may be received, for example, over transceiver 1268 or external interface 1262.

Device 1250 may communicate wirelessly through communication interface 1266, which may include digital signal processing circuitry where necessary. Communication interface 1266 may provide for communications under various modes or protocols, such as GSM voice calls, SMS, EMS, or MMS messaging, CDMA, TDMA, PDC, WCDMA, CDMA2000, or GPRS, among others. Such communication may occur, for example, through radio-frequency transceiver 1268. In addition, short-range communication may occur, such as using a Bluetooth, Wi-Fi, or other such transceiver (not shown). In addition, GPS (Global Positioning System) receiver module 1270 may provide additional navigation- and location-related wireless data to device 1250, which may be used as appropriate by applications running on device 1250.

Device 1250 may also communicate audibly using audio codec 1260, which may receive spoken information from a user and convert it to usable digital information. Audio codec 1260 may likewise generate audible sound for a user, such as through a speaker, e.g., in a handset of device 1250. Such sound may include sound from voice telephone calls, may include recorded sound (e.g., voice messages, music files, etc.) and may also include sound generated by applications operating on device 1250.

The computing device 1250 may be implemented in a number of different forms, as shown in the figure. For example, it may be implemented as a cellular telephone 1280. It may also be implemented as part of a smart phone 1282, personal digital assistant, or other similar mobile device.

While example embodiments may include various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the claims. Like numbers refer to like elements throughout the description of the figures.

Various implementations of the systems and techniques described here can be realized in digital electronic circuitry, integrated circuitry, specially designed ASIC s (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device. Various implementations of the systems and techniques described here can be realized as and/or generally be referred to herein as a circuit, a module, a block, or a system that can combine software and hardware aspects. For example, a module may include the functions/acts/computer program instructions executing on a processor (e.g., a processor formed on a silicon substrate, a GaAs substrate, and the like) or some other programmable data processing apparatus.

Some of the above example embodiments are described as processes or methods depicted as flowcharts. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Methods discussed above, some of which are illustrated by the flow charts, may be implemented by hardware, software, firmware, middleware, microcode, hardware description languages, or any combination thereof. When implemented in software, firmware, middleware or microcode, the program code or code segments to perform the necessary tasks may be stored in a machine or computer readable medium such as a storage medium. A processor(s) may perform the necessary tasks.

Specific structural and functional details disclosed herein are merely representative for purposes of describing example embodiments. Example embodiments, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term and/or includes any and all combinations of one or more of the associated listed items.

It will be understood that when an element is referred to as being connected or coupled to another element, it can be directly connected or coupled to the other element or intervening elements may be present. In contrast, when an element is referred to as being directly connected or directly coupled to another element, there are no intervening elements present. Other words used to describe the relationship between elements should be interpreted in a like fashion (e.g., between versus directly between, adjacent versus directly adjacent, etc.).

The terminology used herein is for the purpose of describing particular embodiments only and is not intended to be limiting of example embodiments. As used herein, the singular forms a, an and the are intended to include the plural forms as well, unless the context clearly indicates otherwise. It will be further understood that the terms comprises, comprising, includes and/or including, when used herein, specify the presence of stated features, integers, steps, operations, elements and/or components, but do not preclude the presence or addition of one or more other features, integers, steps, operations, elements, components and/or groups thereof.

It should also be noted that in some alternative implementations, the functions/acts noted may occur out of the order noted in the figures. For example, two figures shown in succession may in fact be executed concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Portions of the above example embodiments and corresponding detailed description are presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In the above illustrative embodiments, reference to acts and symbolic representations of operations (e.g., in the form of flowcharts) that may be implemented as program modules or functional processes include routines, programs, objects, components, data structures, etc., that perform particular tasks or implement particular abstract data types and may be described and/or implemented using existing hardware at existing structural elements. Such existing hardware may include one or more Central Processing Units (CPUs), digital signal processors (DSPs), application-specific-integrated-circuits, field programmable gate arrays (FPGAs) computers or the like.

It should be borne in mind, however, that all of these and similar terms are to be associated with the appropriate physical quantities and are merely convenient labels applied to these quantities. Unless specifically stated otherwise, or as is apparent from the discussion, terms such as processing or computing or calculating or determining of displaying or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Note also that the software implemented aspects of the example embodiments are typically encoded on some form of non-transitory program storage medium or implemented over some type of transmission medium. The program storage medium may be magnetic (e.g., a floppy disk or a hard drive) or optical (e.g., a compact disk read only memory, or CD ROM), and may be read only or random access. Similarly, the transmission medium may be twisted wire pairs, coaxial cable, optical fiber, or some other suitable transmission medium known to the art. The example embodiments not limited by these aspects of any given implementation.

Lastly, it should also be noted that whilst the accompanying claims set out particular combinations of features described herein, the scope of the present disclosure is not limited to the particular combinations hereafter claimed, but instead extends to encompass any combination of features or embodiments herein disclosed irrespective of whether or not that particular combination has been specifically enumerated in the accompanying claims at this time.

What is claimed is:

1. A method comprising:
associating an ultra-wide band (UWB) tag device with a UWB anchor device;
capturing UWB range and angle data representing a plurality of locations in a physical space using a calibration technique;
capturing UWB range and angle data representing a first location of the UWB tag device in relation to the UWB anchor device;
capturing UWB range and angle data representing a second location of the UWB tag device in relation to the UWB anchor device; and
determining a length based on the first location and the second location.

2. The method of claim 1, wherein at least one range associated with the UWB data is non-linear corrected using a trained polynomial regression model.

3. The method of claim 1, wherein the length is determined as the Euclidean norm of the difference in the cartesian coordinates of the first location and the second location.

4. The method of claim 1, wherein the length is a circumference of a circle that can be determined using a Riemann sum over a set of locations including the first location and the second location.

5. The method of claim 1, wherein the capturing of UWB range and angle data includes
transmitting a first signal from the UWB anchor device to the UWB tag device,
determining a delay time associated with a second signal received, in response to the first signal, by the UWB anchor device from the UWB tag device,
determining a distance based on the delay time,
determining an angle-of-arrival (AoA) based on the first signal and the second signal, and
determining two-dimensional (2D) coordinates corresponding to the location of the UWB tag device.

6. The method of claim 1, wherein the calibration technique is a first calibration technique and the UWB tag device is an element of augmented reality (AR) glasses, the method further comprising:
capturing UWB range and angle data representing a plurality of object locations using a second calibration technique;
associating the UWB range and angle data representing one of the plurality of object locations with the UWB range and angle data representing a first location;
associating UWB range and angle data corresponding to a location of the AR glasses with the UWB range and angle data representing a second location; and
warning a user of the AR glasses when the determined length is less than a threshold length value.

7. The method of claim 1, wherein the calibration technique is a first calibration technique and the UWB tag device is an element of AR glasses, the method further comprising:
capturing UWB range and angle data representing a plurality of object locations using a second calibration technique;
associating the UWB range and angle data representing one of the plurality of object locations with the UWB range and angle data representing a first location;
associating UWB range and angle data corresponding to a location of the AR glasses with the UWB range and angle data representing a second location; and
focusing a camera of the AR glasses based on the determined length.

8. The method of claim 1, wherein the calibration technique is a first calibration technique and the UWB tag device is an element of AR glasses, the method further comprising:
capturing UWB range and angle data representing a plurality of object locations using a second calibration technique;
determining the user of the AR glasses is focused on an object of the plurality of objects; and
in response to determining the user of the AR glasses is focused on an object of the plurality of objects
associating the UWB range and angle data representing the object location with the UWB range and angle data representing a first location,
associating UWB range and angle data corresponding to a location of the AR glasses with the UWB range and angle data representing a second location, and
zooming a lens of a camera of the AR glasses based on the determined length for displaying the object on a display of the AR glasses.

9. The method of claim 1, wherein the calibration technique is a first calibration technique and the UWB tag device is an element of AR glasses, the method further comprising:
capturing UWB range and angle data representing a plurality of object locations using a second calibration technique;
determining the user of the AR glasses is looking for an object of the plurality of objects; and
in response to determining the user of the AR glasses is looking for an object of the plurality of objects
associating the UWB range and angle data representing the object location with the UWB range and angle data representing a first location,
associating UWB range and angle data corresponding to a location of the remaining objects of the plurality of objects with the UWB range and angle data representing a second location, and
blurring or focusing a display of the AR glasses based on the determined length.

10. The method of claim 1, wherein the calibration technique is a first calibration technique and the UWB tag device is an element of AR glasses, the method further comprising:
capturing UWB range and angle data representing a plurality of object locations using a second calibration technique;
associating UWB range and angle data a virtual reality (VR) object;
associating the UWB range and angle data representing the VR object location with the UWB range and angle data representing a first location;
associating UWB range and angle data corresponding to a location of the AR glasses with the UWB range and angle data representing a second location;
determining whether the user of the AR glasses is within a range of the VR object based on the determined length; and
in response to determining whether the user of the AR glasses is within the range of the VR object, initiating a VR action by the VR object.

11. The method of claim 1, wherein the calibration technique is a first calibration technique and the UWB tag device is an element of AR glasses, the method further comprising:
capturing UWB range and angle data representing a plurality of object locations using a second calibration technique;
associating UWB range and angle data a virtual reality (VR) object;
associating the UWB range and angle data representing the VR object location with the UWB range and angle data representing a first location;
associating UWB range and angle data corresponding to a location of the objects of the plurality of objects with the UWB range and angle data representing a second location;
determining the user of the VR glasses is looking at the VR object; and
in response to determining the user of the VR glasses is looking at the VR object, adjusting an opaqueness of the VR object based on the plurality of objects along a line of sight and the determined length.

12. The method of claim 1, wherein the calibration technique is a first calibration technique, the method further comprising:
capturing UWB range and angle data representing a plurality of object locations using a second calibration technique;
determining a user in possession of the UWB tag device has initiated a media casting operation; and
in response to determining the user has initiated a media casting operation
associating the UWB range and angle data representing each of the plurality of object locations with the UWB range and angle data representing a first location,
associating UWB range and angle data corresponding to a location of the AR glasses with the UWB range and angle data representing a second location,
determining whether a device capable of receiving and displaying the media casting is within a range of the user based on the determined length, and
in response to determining a device capable of receiving and displaying the media casting is within the range of the user, casting the media to the device.

13. The method of claim 12, further comprising:
determining the user is no longer in range of the device capable of receiving and displaying the media based on the length;
determining the user is in range of a second device capable of receiving and displaying the media based on the determined length; and
in response to determining second device capable of receiving and displaying the media casting is within the range of the user, ending the casting of the media to the device and casting the media to the second device.

14. The method of claim 1, wherein the calibration technique is a first calibration technique, the method further comprising:
capturing UWB range and angle data representing a plurality of light locations using a second calibration technique;
associating the UWB range and angle data representing one of the plurality of light locations with the UWB range and angle data representing a first location;
associating UWB range and angle data corresponding to a location of a user in possession of the UWB tag device with the UWB range and angle data representing a second location;
determining whether the user is within a range of a light based on the determined length;
in response to determining whether the user is within the range of a light, causing the light to turn on; and
in response to determining whether the user is not within the range of a light, causing the light to turn off.

15. A system comprising:
an ultra-wide band (UWB) tag device; and
a UWB anchor device communicatively coupled with the UWB tag device, the system configured to:
capture UWB range and angle data representing a plurality of locations in a physical space using a calibration technique,
capture UWB range and angle data representing a first location of the UWB tag device in relation to the UWB anchor device,
capture UWB range and angle data representing a second location of the UWB tag device in relation to the UWB anchor device, and
determine a length based on the first location and the second location.

16. The system of claim 15, wherein at least one range associated with the UWB data is non-linear corrected using a trained polynomial regression model.

17. The system of claim 15, wherein the length is determined as the Euclidean norm of the difference in the cartesian coordinates of the first location and the second location.

18. The system of claim 15, wherein the length is a circumference of a circle that can be determined using a Riemann sum over a set of locations including the first location and the second location.

19. The system of claim 15, wherein the capturing of UWB range and angle data includes
transmitting a first signal from the UWB anchor device to the UWB tag device,
determining a delay time associated with a second signal received, in response to the first signal, by the UWB anchor device from the UWB tag device,
determining a distance based on the delay time,
determining an angle-of-arrival (AoA) based on the first signal and the second signal, and
determining two-dimensional (2D) coordinates corresponding to the location of the UWB tag device.

20. The system of claim 15, wherein the calibration technique is a first calibration technique and the UWB tag device is an element of augmented reality (AR) glasses, the system further configured to:
capture UWB range and angle data representing a plurality of object locations using a second calibration technique;
associate the UWB range and angle data representing one of the plurality of object locations with the UWB range and angle data representing a first location;
associate UWB range and angle data corresponding to a location of the AR glasses with the UWB range and angle data representing a second location; and
warn a user of the AR glasses when the determined length is less than a threshold length value.

21. The system of claim 15, wherein the calibration technique is a first calibration technique and the UWB tag device is an element of AR glasses, the system further configured to:
capture UWB range and angle data representing a plurality of object locations using a second calibration technique;
associate the UWB range and angle data representing one of the plurality of object locations with the UWB range and angle data representing a first location;
associate UWB range and angle data corresponding to a location of the AR glasses with the UWB range and angle data representing a second location; and
focus a camera of the AR glasses based on the determined length.

22. The system of claim 15, wherein the calibration technique is a first calibration technique and the UWB tag device is an element of AR glasses, the system further configured to:
capture UWB range and angle data representing a plurality of object locations using a second calibration technique;
determine the user of the AR glasses is focused on an object of the plurality of objects; and
in response to determining the user of the AR glasses is focused on an object of the plurality of objects
associate the UWB range and angle data representing the object location with the UWB range and angle data representing a first location,
associate UWB range and angle data corresponding to a location of the AR glasses with the UWB range and angle data representing a second location, and
zoom a lens of a camera of the AR glasses based on the determined length for displaying the object on a display of the AR glasses.

23. The system of claim 15, wherein the calibration technique is a first calibration technique and the UWB tag device is an element of AR glasses, the system further configured to:
capture UWB range and angle data representing a plurality of object locations using a second calibration technique;
determine the user of the AR glasses is looking for an object of the plurality of objects; and
in response to determining the user of the AR glasses is looking for an object of the plurality of objects
associate the UWB range and angle data representing the object location with the UWB range and angle data representing a first location,
associate UWB range and angle data corresponding to a location of the remaining objects of the plurality of objects with the UWB range and angle data representing a second location, and
blur or focus a display of the AR glasses based on the determined length.

24. The system of claim 15, wherein the calibration technique is a first calibration technique and the UWB tag device is an element of AR glasses, the system further configured to:
capture UWB range and angle data representing a plurality of object locations using a second calibration technique;
associate UWB range and angle data a virtual reality (VR) object;
associate the UWB range and angle data representing the VR object location with the UWB range and angle data representing a first location;
associate UWB range and angle data corresponding to a location of the AR glasses with the UWB range and angle data representing a second location;
determine whether the user of the AR glasses is within a range of the VR object based on the determined length; and
in response to determining whether the user of the AR glasses is within the range of the VR object, initiate a VR action by the VR object.

25. The system of claim 15, wherein the calibration technique is a first calibration technique and the UWB tag device is an element of AR glasses, the system further configured to:
capture UWB range and angle data representing a plurality of object locations using a second calibration technique;
associate UWB range and angle data a virtual reality (VR) object;
associate the UWB range and angle data representing the VR object location with the UWB range and angle data representing a first location;
associate UWB range and angle data corresponding to a location of the objects of the plurality of objects with the UWB range and angle data representing a second location;
determine the user of the VR glasses is looking at the VR object; and
in response to determining the user of the VR glasses is looking at the VR object, adjust an opaqueness of the VR object based on the plurality of objects along a line of sight and the determined length.

26. The system of claim 15, wherein the calibration technique is a first calibration technique, the method further comprising:
capture UWB range and angle data representing a plurality of object locations using a second calibration technique;
determine a user in possession of the UWB tag device has initiated a media casting operation; and
in response to determining the user has initiated a media casting operation
associate the UWB range and angle data representing each of the plurality of object locations with the UWB range and angle data representing a first location,
associate UWB range and angle data corresponding to a location of the AR glasses with the UWB range and angle data representing a second location,
determine whether a device capable of receiving and displaying the media casting is within a range of the user based on the determined length, and
in response to determining a device capable of receiving and displaying the media casting is within the range of the user, cast the media to the device.

27. The system of claim 26, further configured to:
determine the user is no longer in range of the device capable of receiving and displaying the media based on the length;
determine the user is in range of a second device capable of receiving and displaying the media based on the determined length; and
in response to determining second device capable of receiving and displaying the media casting is within the range of the user, end the casting of the media to the device and cast the media to the second device.

28. The system of claim 15, wherein the calibration technique is a first calibration technique, the system further configured to:
capture UWB range and angle data representing a plurality of light locations using a second calibration technique;
associate the UWB range and angle data representing one of the plurality of light locations with the UWB range and angle data representing a first location;
associate UWB range and angle data corresponding to a location of a user in possession of the UWB tag device with the UWB range and angle data representing a second location;
determine whether the user is within a range of a light based on the determined length;
in response to determining whether the user is within the range of a light, cause the light to turn on; and
in response to determining whether the user is not within the range of a light, cause the light to turn off.

29. A non-transitory computer readable medium containing instructions that when executed cause a processor of a computer system to perform steps comprising:
associating an ultra-wide band (UWB) tag device with a UWB anchor device;
capturing UWB range and angle data representing a plurality of locations in a physical space using a calibration technique;
capturing UWB range and angle data representing a first location of the UWB tag device in relation to the UWB anchor device;
capturing UWB range and angle data representing a second location of the UWB tag device in relation to the UWB anchor device; and
determining a length based on the first location and the second location.
